(19) United States
(12) Patent Application Publication
(10) Pub. No.: US 2024/0347590 A1
(43) Pub. Date: Oct. 17, 2024

(54) METHODS AND APPARATUS TO REDUCE STRESS IN INTEGRATED CIRCUIT PACKAGES

(71) Applicant: Intel Corporation, Santa Clara, CA (US)

(72) Inventors: Bhaskar Jyoti Krishnatreya, Hillsboro, OR (US); Guruprasad Arakere, Chandler, AZ (US); Nitin Ashok Deshpande, Chandler, AZ (US); Mohammad Enamul Kabir, Portland, OR (US); Omkar Gopalkrishna Karhade, Chandler, AZ (US); Keith Edward Zawadzki, Portland, OR (US); Trianggono S. Widodo, Hillsboro, OR (US)

(21) Appl. No.: 18/755,306

(22) Filed: Jun. 26, 2024

(51) Int. Cl. H01L 29/06; H01L 21/306; H01L 21/3065; H01L 21/78; H01L 23/00; H01L 25/065

(52) U.S. Cl. CPC H01L 29/0657; H01L 21/78; H01L 23/562; H01L 25/0655; H01L 21/30625; H01L 21/3065; H01L 24/08; H01L 2224/08221

(57) ABSTRACT

Systems, apparatus, articles of manufacture, and methods to reduce stress in integrated circuit packages are disclosed. An example semiconductor chip includes: a front surface; a back surface opposite the front surface; a first lateral surface extending between the front surface and the back surface; a second lateral surface extending between the front surface and the back surface; and a curved fillet at an intersection between the first lateral surface and the second lateral surface.

### BACKGROUND

Frequently, multiple integrated circuits are initially fabricated on a single semiconductor wafer or panel. Once the integrated circuits have been fabricated, they are separated into separate chips or dies through various singulation processes. Once the chips are singulated, they can be packaged. In some packaging processes, different chips are reconstituted on a carrier to enable different chips to be combined in a single package using wafer-to-wafer and/or chip-to-wafer bonding processes.

### BRIEF DESCRIPTION OF THE DRAWINGS

FIG. 1 represents an integrated circuit (IC) chip (e.g., a die) constructed in accordance with known fabrication processes.

FIG. 2 is a top view of a wafer that includes multiple instances of the IC chip of FIG. 1

FIG. 3 includes a top view and a cross-sectional side view of an IC package that includes the IC chip of FIG. 1.

FIG. 4 includes a top view and a cross-sectional side view of a reconstituted wafer including a plurality of the different chips (some of which correspond to the IC chip of FIG. 1).

FIG. 5 illustrates an example IC chip (e.g., die) constructed in accordance with teachings disclosed herein.

FIG. 6 is a top view of an example wafer that includes multiple instances of the example IC chip of FIG. 5.

FIG. 7 includes a top view and a cross-sectional side view of an example IC package that includes the example IC chip of FIG. 5.

FIG. 8 includes a top view and a cross-sectional side view of an example reconstituted wafer including a plurality of the different chips (some of which correspond to the example IC chip of FIG. 5).

FIG. 9 illustrates another example IC chip constructed in accordance with teachings disclosed herein.

FIG. 10 illustrates another example IC chip constructed in accordance with teachings disclosed herein.

FIG. 11 is a cross-sectional view of an example IC package constructed in accordance with teachings disclosed herein.

FIGS. 12-18 illustrate example stages during the fabrication process of the example IC package of FIG. 11.

FIGS. 19-22 illustrate different stages in an alternative example fabrication process to produce individual chips with a rounded bevel along a perimeter of the back surface of the chips.

FIG. 23 illustrates a top view of another example IC chip constructed in accordance with teachings disclosed herein.

FIG. 24 is a flowchart representative of an example method that may be performed to fabricate an IC package based on the stages of fabrication represented in FIGS. 12-18.

FIG. 25 is a flowchart representative of an example method that may be performed to fabricate an IC package based on the stages of fabrication represented in FIGS. 19-22.

FIG. 26 is a cross-sectional side view of an IC device that may be included in an IC package constructed in accordance with teachings disclosed herein.

FIG. 27 is a cross-sectional side view of an IC package constructed in accordance with teachings disclosed herein.

FIG. 28 is a cross-sectional side view of an IC device assembly that may include an IC package constructed in accordance with teachings disclosed herein.

FIG. 29 is a block diagram of an example electrical device that may include an IC package constructed in accordance with teachings disclosed herein.

In general, the same reference numbers will be used throughout the drawing(s) and accompanying written description to refer to the same or like parts. The figures are not necessarily to scale. Instead, the thickness of the layers or regions may be enlarged in the drawings. Although the figures show layers and regions with clean lines and boundaries, some or all of these lines and/or boundaries may be idealized. In reality, the boundaries and/or lines may be unobservable, blended, and/or irregular.

### DETAILED DESCRIPTION

FIG. 1 represents a known integrated circuit (IC) chip 100 (e.g., a die) constructed in accordance with known fabrication processes. As shown, the IC chip 100 includes a bulk semiconductor substrate 102, a front-end-of-line (FEOL) process area 104, and a back-end-of-line (BEOL) process area 106. As shown in FIG. 1, the BEOL process area 106 is on a first side of the chip 100 (e.g., the bottom side of the chip 100 based on the orientation shown in FIG. 1) corresponding to and/or defining a front surface 108 (e.g., front side, first surface) of the IC chip 100. Further, the backside of the bulk semiconductor substrate 102 is on a first side of the chip 100 corresponding to and/or defining a back surface 110 (e.g., back side, second surface) of the IC chip 100. It should be appreciated that different designs for IC chips are possible from what is shown in FIG. 1. For instance, some IC chips are implemented with back side power delivery. In some such chips, power delivery layers and signal layers (both typically associated with the BEOL process area 106) can be on opposite sides of the FEOL process area 104. That is, some chips include the FEOL process area 104 between power delivery layers on one side of the FEOL process area 104 (closest to the bulk semiconductor substrate 102) and signal layers (farthest from the bulk semiconductor substrate 102) on the other side of the FEOL process area 104.

As shown in FIG. 1, the IC chip 100 has four lateral surfaces 112, 114, 116, 118 that extend between the front surface 108 and the back surface 110 of the IC chip 100. In known IC chips, such as the IC chip 100 of FIG. 1, the lateral surfaces 112, 114, 116, 118 are substantially perpendicular to the front and back surfaces 108, 110. As a result, the front and back surfaces 108, 110 have respective perimeters 120, 122 defined by discrete edges or intersections 124 between (e.g., at the interface of, connecting) the lateral surfaces 112, 114, 116, 118 and the front and back surfaces 108, 110. Further, adjacent ones of the lateral surfaces 112, 114, 116, 118 are substantially perpendicular to one another to define a rectangular (e.g., square) shape or footprint for the IC chip 100 with discrete edges or intersections 126 between (e.g., at the interface of, connecting) adjacent ones of the lateral surfaces 112, 114, 116, 118. For purposes of distinction, the edges or intersections 124 along the perimeters 120, 122 of the front and back surfaces 108, 110 are referred to herein as perimeter edges or perimeter intersections, whereas the edges or intersections 126 between adjacent lateral surfaces 112, 114, 116, 118 are referred to herein as lateral edges or lateral intersections.

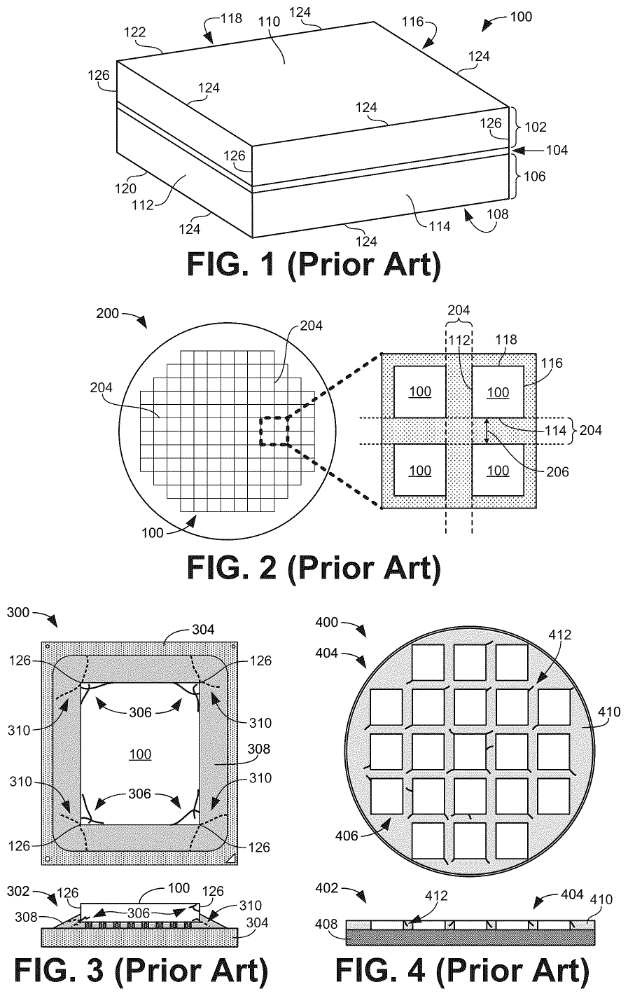

The substantially perpendicular angles between different ones of the lateral surfaces 112, 114, 116, 118 and between the lateral surfaces 112, 114, 116, 118 and the front and back surfaces 108, 110 are created as a result of a singulation process. During the singulation process the chip (along with multiple other chips) is cut from a semiconductor wafer with a diamond-based saw blade. Typically, saw based dicing can only be done along straight lines from one end of the wafer/panel to the other end of the wafer/panel and leads to rectangular shaped singulated chips with 90-degree corners. Specifically, FIG. 2 is a top view of a wafer 200 that includes multiple instances of the chip 100 of FIG. 1 on which circuitry components (e.g., transistors, interconnects, etc.) are fabricated during the FEOL and BEOL processes. The wafer 200 includes semiconductor material (e.g., silicon) corresponding to the bulk semiconductor substrate 102 of the IC chip 100 of FIG. 1. After completion of both the FEOL and BEOL processes to fabricate circuitry on the wafer 200, the wafer 200 may undergo a singulation process in which the chips 100 are separated from one another by a saw cutting along lines defined between the chips 100. The lines defining the path of the saw are also known as saw streets or scribe lines 204. The scribe lines 204 have a width 206 (greatly exaggerated relative to the size of the chips 100 in the enlarged inset of FIG. 2) that corresponds to the width of the saw. Thus, the passing of the saw along the scribe lines 204 establishes and/or defines the lateral surfaces 112, 114, 116, 118 of the chips 100 as well as the corresponding edges 124, 126 between the different (e.g., front, back, and lateral) surfaces of the chips 100. Further, as shown in FIG. 2, the scribe lines 204 extend in straight lines. As a result, the lateral surfaces 112, 114, 116, 118 of each resulting chip 100 are planar.

Furthermore, different scribe lines 204 extend substantially perpendicular to one another such that adjacent ones of the planar lateral surfaces 112, 114, 116, 118 end up being substantially perpendicular to one another. More particularly, the singulation of any given chip 100 in the wafer 200 involves four separate cuts with a saw. Each of the four cuts serves to establish and/or define one of the four lateral surfaces 112, 114, 116, 118 of the corresponding chip 100 and the resulting edges 126 (e.g., corners) of the chip 100 at the intersection of the lateral surfaces 112, 114, 116, 118. Inasmuch as the scribe lines 204 extend all or substantially all the way across the wafer (e.g., at least across multiple individual chips 100), intersecting scribe lines 204 cross one another to produce the lateral edges 126 (e.g., corners) between (e.g., at the interface or intersection of) adjacent ones of the lateral surfaces 112, 114, 116, 118. Further, inasmuch as the saw is substantially perpendicular to the plane of the wafer 200 during singulation, the saw cuts also produce the perimeter edges 124 between (e.g., at the interface or intersection of) the front and back surfaces 108, 110 of the chip 100.

Due to the nature of the saw cuts, the resulting edges 124, 126 result in relatively sharp and/or abrupt corners. As used herein, a sharp corner and/or an abrupt corner is defined to be an intersection between two surfaces where the intersection defines and/or includes an angular discontinuity. That is, the two surfaces intersect at different angles without a smooth (e.g., curved) transition between the different angles or the different surfaces. Notably, the angle between the two surfaces is not relevant to whether the corner between the surfaces is sharp and/or abrupt. In FIGS. 1 and 2, the edges 124, 126 are corners defined by 90 degree turns. However, different angles, either less than 90 degrees or more than 90 degrees, can still be considered sharp and/or abrupt, as defined herein, so long as the corner defines an angular discontinuity between the two surfaces rather than a smooth (e.g., curved) transition between the surfaces. In other words, the sharpness and/or abruptness of a corner can be defined in terms of the radius of curvature of the corner. As used herein, a sharp corner and/or an abrupt corner is a corner with a radius of curvature of less than 1 micrometer. By contrast, corners with a radius of curvature greater than 1 micrometer (e.g., at least 2 micrometers, at least 3 micrometers, at least 5 micrometers, at least 10 micrometers, at least 20 micrometers, at least 25 micrometers, at least 50 micrometers, etc.) are referred to herein as rounded corners. Using straight saw cuts, as shown in FIG. 2, it is not possible to produce chips 100 with rounded corners.

The sharp or abrupt corners along the edges 124, 126 of a chip 100 create mechanical stress points that can result in problems during subsequent packaging processes. For instance, after singulation, individual chips 100 can be moved through a pick-and-place process onto a package substrate 304 as represented in the top view 300 and the cross-sectional side view 302 in FIG. 3. The pick-and-place process can result in internal cracks 306 developing in the area of the sharp or abrupt corners of the chip 100 associated with the lateral edges 126. Furthermore, after the chip 100 is mounted to the package substrate 304, an underfill material 308 may be applied. In some instances, the sharp or abrupt corners of the chip 100 serve as stress points to cause propagation of external cracks 310 in the surrounding (underfill) material 308. Similar cracks can result in the surrounding material of a reconstituted wafer as represented in FIG. 4. Specifically, FIG. 4 shows a top view 400 and a cross-sectional side view 402 of a reconstituted wafer 404 including a plurality of different chips 406 (some of which may correspond to the IC chip of FIG. 1) mounted on a substrate 408 (e.g., a carrier wafer). In FIG. 4, the different chips 406 are spaced apart with the gap(s) therebetween filled with an inorganic and/or an organic fill material 410. The sharp or abrupt corners of the chips 406 serve as stress points to cause propagation of external cracks 412 in the surrounding fill material 410. In many instances, the fill material 410 on the reconstituted wafer 404 is deposited up to the full thickness of the chips 406 and sometimes even beyond the outer surface of the chips 406. As a result, the entire length of the lateral edges 126 of the chips 406 and possibly even the perimeter edges 124 on the outer surface of the chips 406 can define a stress point to initiate an external crack 412.

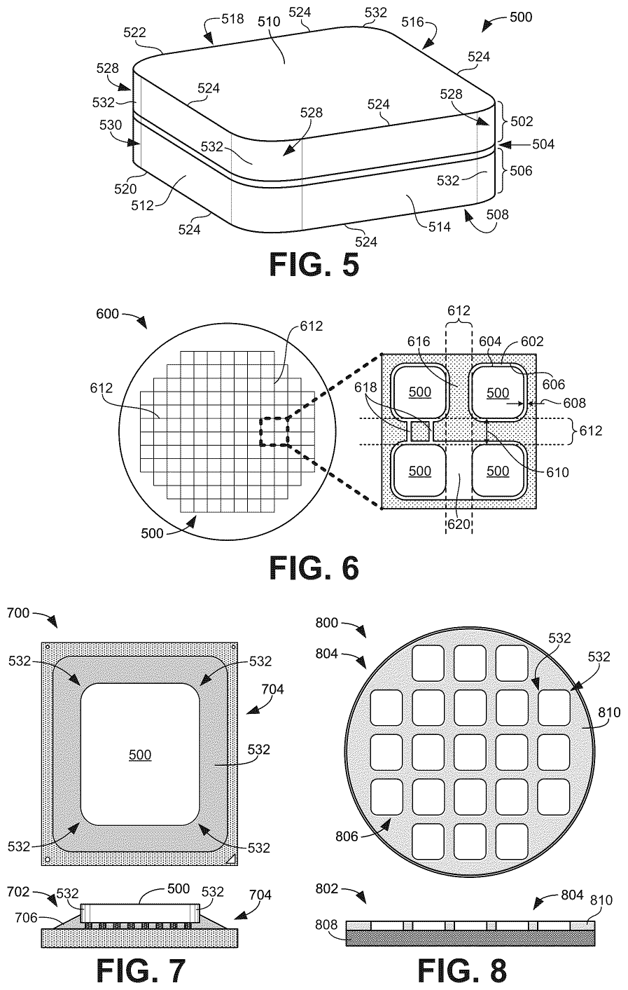

Examples disclosed herein reduce (e.g., minimize) the onset of cracks both internal to a chip and external to the chip by fabricating the chip with rounded corners at some or all of the edges of the chip. Specifically, FIG. 5 illustrates an example IC chip 500 (e.g., die) constructed in accordance with teachings disclosed herein. The example chip 500 may include and/or implement a memory device (e.g., a random access memory (RAM) device, such as a static RAM (SRAM) device, a magnetic RAM (MRAM) device, a resistive RAM (RRAM) device, a conductive-bridging RAM (CBRAM) device, etc.), a logic device (e.g., an AND, OR, NAND, or NOR gate), or any other suitable circuitry or electronics. As shown, the example IC chip 500 includes a bulk semiconductor substrate 502, a front-end-of-line (FEOL) process area 504, and a back-end-of-line (BEOL) process area 506. The FEOL process area 504 includes active semiconductor devices (e.g., transistors) fabricated on the bulk semiconductor substrate 502 (e.g., a semiconductor wafer). The BEOL process area 506 includes conductive interconnects that electrically couple the transistors and provide paths for signals and power between the transistors and contact pads on an outer surface of the chip 500 to enable the chip 500 to be electrically coupled to external components. In some examples, the FEOL and/or the BEOL process areas 504, 506 can include any other suitable electronic component(s) (e.g., capacitor(s), inductor(s), etc.). The side of the bulk semiconductor substrate 502 on which the FEOL process area 504 is fabricated (and on which the BEOL process area 506 is subsequently fabricated) is referred to as the frontside of the substrate 502 with the opposite side being referred to as the backside of the substrate 502. Following this nomenclature, the outer surface of the BEOL process area 506 where contact pads are located (e.g., the bottom side of the chip 500 based on the orientation shown in FIG. 5) corresponds to and/or defines a front surface 508 (e.g., front side, first surface) of the IC chip 500. Further, the backside of the bulk semiconductor substrate 502 corresponds to and/or defines a back surface 510 (e.g., back side, second surface) of the IC chip 500. It should be appreciated that different designs for the example IC chip 500 are possible from what is shown in FIG. 5. For instance, in some examples, the IC chip 500 may be implemented with back side power delivery. In some such examples, power delivery layers and signal layers (both typically associated with the BEOL process area 506) can be on opposite sides of the FEOL process area 504. That is, in some examples, the FEOL process area 504 is between power delivery layers on one side of the FEOL process area 504 (closest to the bulk semiconductor substrate 502 with through silicon vias that extend to the back surface 510) and signal layers (farthest from the bulk semiconductor substrate 502) on the other side of the FEOL process area 504. In such examples, the side of the bulk semiconductor substrate 502 opposite the FEOL and BEOL process areas 504, 506 (however arranged) still corresponds to the backside of the IC chip 500 and the opposite side is the front side of the IC chip 500.

As shown in illustrated example of FIG. 5, the IC chip 500 has four lateral surfaces 512, 514, 516, 518 that extend between the front surface 508 and the back surface 510 of the IC chip 500. In this example, the lateral surfaces 512, 514, 516, 518 are substantially perpendicular to the front and back surfaces 508, 510 with the front and back surfaces 508, 510 having respective perimeters 520, 522 defined by edges or intersections 524 between (e.g., at the interface of, connecting) the lateral surfaces 512, 514, 516, 518 and the front and back surfaces 508, 510. Adjacent ones of the lateral surfaces 512, 514, 516, 518 are substantially perpendicular to one another to define a generally rectangular (e.g., square) shape or footprint for the IC chip 500. However, unlike the known IC chip 100 of FIG. 1, the example IC chip 500 of FIG. 5 includes lateral edges 528 (e.g., intersections) between adjacent ones of the lateral surfaces 512, 514, 516, 518 that are rounded and/or define a smooth transition between the intersecting lateral surfaces 512, 514, 516, 518. That is, in this example, the different lateral surfaces 512, 514, 516, 518 correspond to different segments of a lateral sidewall 530 of the IC chip 500 that extends all the way around the perimeters 520, 522 of the front and back surfaces 508, 510 of the chip 500 without any angular discontinuities despite the different segments (e.g., the different lateral surfaces 512, 514, 516, 518) being angled relative to one another. That is, the lateral sidewall 530 is devoid of any sharp or abrupt corners (e.g., any corners having a radius of curvature of less than 1 micrometer). Thus, while example IC chip 500 has a footprint exhibiting a rectangular (e.g., square) shape, the shape of the footprint more particularly corresponds to a rectangle with rounded corners. In other words, instead of having lateral edges 126 defined by sharp or abrupt corners, as shown in FIG. 1, the lateral edges 528 of the example chip 500 of FIG. 5 are defined by curved fillets 532 (e.g., round fillets) extending along a length of the edges 528 between adjacent ones of the lateral surfaces 512, 514, 516, 518. In the illustrated example, the curved fillets 532 extend a full distance of the length of the edges 528 defined between the front and back surfaces 508, 510 of the chip 500.

In the illustrated example of FIG. 5, adjacent ones of the lateral surfaces 512, 514, 516, 518 are substantially perpendicular. As a result, the example chip 500 has a footprint exhibiting by a rectangular (e.g., square) shape with rounded corners. As described in greater detail below, in some examples, a saw is not relied on to cut the lateral surfaces 512, 514, 516, 518 of the chip 500 or to form the rounded corners. Briefly, in some examples, stealth dicing and/or plasma etch based dicing techniques for semiconductor wafer dicing may be used to isolate (e.g., singulate the chip 500 form a wafer). Unlike saw-based dicing that is limited to straight cuts and, thus, rectangular shaped chips, plasma dicing and stealth dicing allow for singulation of chips into any suitable (e.g., arbitrary) shapes. In some examples, stealth dicing can be implemented in combination with other processes such as galvo based laser ablation used to ablate material (e.g., remove the dielectrics and/or metals from) along any desired path (e.g., along the scribe lines) followed by stealth dicing. Thus, the shape of the chip 500 is not limited to a rectangle defined by four straight cuts with a saw. Rather, in some examples, the footprint of the chip 500 can have any suitable shape. In some examples, the footprint of the chip is any suitable polygon shape with rounded corners. In some examples, none of the rounded corners have a radius of curvature less than 2 micrometers. As a result, the example chip 500 of FIG. 5 includes no sharp or abrupt corners that produce stress points that could create cracks unlike the case with known IC chips 100 shown in FIGS. 3 and 4. In some examples, the radius of curvature can be significantly greater than 2 micrometers (e.g., at least 5 micrometers, at least 10 micrometers, at least 50 micrometers, at least 100 micrometers, at least 200 micrometers, at least 250 micrometers, at least 500 micrometers, at least 800 micrometers, at least 1000 micrometers (e.g., 1 millimeter), multiple millimeters, etc.)

FIG. 6 is a top view of an example wafer 600 that includes multiple instances of the chip 500 of FIG. 5. The wafer 600 includes semiconductor material (e.g., silicon) corresponding to the bulk semiconductor substrate 502 of the IC chip 500 of FIG. 5 on which circuitry components (e.g., transistors, interconnects, etc.) are fabricated during the FEOL and BEOL processes. After completion of both the FEOL and BEOL processes, the wafer 600 may undergo a singulation process in which the chips 500 are separated from one another. However, unlike known chips, such as the chips 100 described in connection with FIG. 2, in the illustrated example of FIG. 6, a saw is not used to cut out the individual chips 500. Rather, in some examples, singulation is achieved through other dicing techniques (e.g., stealth dicing, plasma etching, etc.) that cuts through the entire wafer 600 including through the bulk semiconductor substrate 502, the FEOL process area 504, and the BEOL process area 506. More particularly, in some examples, a mask (e.g., a photoresist) is deposited across the wafer 600 and photolithographically patterned to expose etch regions 602 that surround the area of each individual chip 500, as shown in the enlarged inset image in FIG. 6. In this example, the inner surface 604 (e.g., inner wall) of a given etch region 602 defines the sidewall 530 (e.g., the lateral surfaces 512, 514, 516, 518) of the corresponding chip 500. Accordingly, in some examples, the mask is patterned so that the etch regions 602 have rounded corners on the inner surface 604 that correspond to the desired shape of the rounded edges 528 on the chip 500 shown in FIG. 5.

In the illustrated example of FIG. 6, the outer surface 606 of the etch region 602 also includes rounded corners. However, in other examples, the outer surface 606 of the etch region 602 can include any other suitable shape and does not need to match or correspond to the shape (e.g., the rounded corners) of the inner surface 604. In some examples, as shown in FIG. 6, the etch region 602 associated with a given chip 500 is separate and spaced apart from etch regions 602 for adjacent chips 500. That is, in some examples, a thickness 608 of the etch region 602 (e.g., a distance between the inner and outer surfaces 604, 606 of the etch region 602) is less than a width 610 of the scribe lines 612 between the adjacent chips 500 with a portion 616 of the wafer 600 being retained between adjacent chips 500 after the singulation (etching) process. This is different than the result of existing singulation processes where all of the wafer between adjacent chips is removed by a saw passing along the corresponding scribe line (e.g., the scribe lines 204 of FIG. 2) because, as described above, the width 206 of the scribe line 204 generally corresponds to the thickness of the saw.

In some examples the thickness 608 of the etch regions 602 in FIG. 6 is less than the thickness of a saw used for singulation. For instance, the thickness or width for a diamond-based saw can differ between different applications but often ranges from between 25 micrometers and as much as 200 micrometers or more. Thus, it is not possible to make cuts through a wafer using a saw that are less than 25 micrometers (or more depending on the saw used). By contrast, the thickness 608 of an etch region can be significantly less (e.g., less than 25 micrometers, less than 20 micrometers, less than 15 micrometers, less than 10 micrometers, less than 5 micrometers, etc.). As a result, in some examples, the width 610 of the scribe lines 612 can be less than the width 206 of the scribe lines 204 made by a singulation saw as discussed above in connection with FIG. 2. Accordingly, in some examples, there is additional space on a given wafer 600 that can be used to fabricate additional and/or larger chips 500 across the fixed size of the wafer 600 based on the chips 500 being placed closer together. In other words, in some examples, more chips per wafer can be produced and/or larger chips can be produced than possible for a given wafer size using a saw-based singulation process. In some examples, the distance between adjacent ones of the chips 500 (e.g., the width 610 of the corresponding scribe line 612) corresponds to the thickness 608 of one of the etch regions 602. That is, in some examples, etch regions 602 around two adjacent chips 500 are combined and/or overlap in the space between the chips 500. Additionally or alternatively, in some examples, separate etch regions 602 surrounding adjacent chips 500 are connected by one or more additional etch regions 618 that extend transverse to an associated scribe line 612 across the portion 616 of the wafer 600 between the etch regions 602 surrounding the chips 500. In some examples, the entire portion 616 of the wafer 600 between adjacent chips 500 can be etched away as represented by the etch region identified by reference 620 in FIG. 6. In some examples, the various etch regions 602, 618, 620 are defined to correspond with metal free zones within the wafer 600. In this manner it is possible to etch through the entire wafer 600 (e.g., including the bulk semiconductor substrate 502, the FEOL process area 504, and the BEOL process area 506) with a plasma etch and/or other dicing technique (e.g., stealth dicing).

FIG. 7 illustrates a top view 700 and a cross-sectional side view 702 of an example IC package 704 that includes the example IC chip 500 of FIG. 5. As shown in the illustrated example, the chip 500 includes the rounded corners or fillets 532. The curved fillets 532 reduce mechanical stress, thereby reducing (e.g., eliminating) the creation of internal cracks within the chip as well as external cracks within the underfill material 706 surrounding the chip 500.

FIG. 8 illustrates a top view 800 and a cross-sectional side view 802 of an example reconstituted wafer 804 including a plurality of the different chips 406 (some of which correspond to the example IC chip 500 of FIG. 5) mounted on a substrate 808 (e.g., a carrier wafer). As with the reconstituted wafer 404 of FIG. 4, the chips 806 in FIG. 8 are spaced apart with the gap therebetween filled with an inorganic and/or an organic fill material 810. However, unlike what is shown in FIG. 4, the fill material 810 does not include cracks because the chips 500 have the rounded fillets 532 to reduce (e.g., prevent) the formation of such cracks.

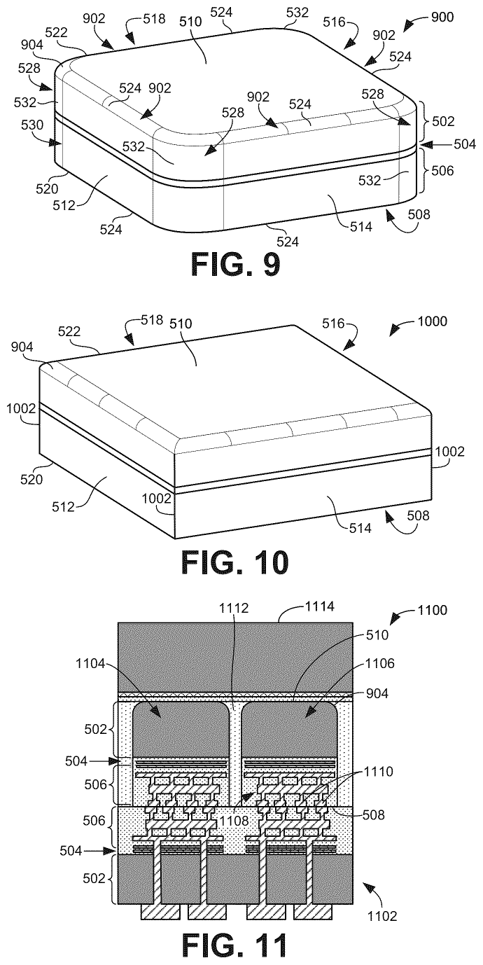

FIG. 9 illustrates another example IC chip 900 constructed in accordance with teachings disclosed herein. The same reference numbers are used for the same or similar features shown in FIG. 9 as shown in FIG. 5. Further, the description of such features provided above in connection with FIG. 5 applies similarly to the corresponding features shown in FIG. 9. Thus, as shown in FIG. 9, the example chip 900 includes a bulk semiconductor substrate 502, a FEOL process area 504, and a BEOL process area 506 as described above. In this example, the chip 900 includes four lateral surfaces 512, 514, 516, 518 that extend between front and back surfaces 508, 510. As in FIG. 5, the lateral surfaces 512, 514, 516, 518 of the example IC chip 900 of FIG. 9 are connected at lateral intersections or edges 528 defined by curved fillets 532 (e.g., rounded corners). While the lateral edges 528 of the example chip 500 of FIG. 5 are rounded, the perimeter edges 524 along the perimeters 520, 522 of the front and back surfaces 508, 510 are defined by sharp or abrupt corners. By contrast, in the illustrated example of FIG. 9, the perimeter edges 524 along the perimeter 522 of the back surface 510 are defined by rounded corners 902. In some examples, the rounded perimeter edges 524 combine to define a rounded bevel 904 that extends around the entire perimeter 522 of the back surface 510.

In some examples, the rounded perimeter edges 524 are provided through a chemical mechanical planarization (CMP) process. Specifically, a CMP process involves pressing a surface of a wafer that need to be planarized against a CMP pad to a controlled pressure across the wafer. Both the wafer and the pad are rotated) at a controlled rotational speed. Depending on the nature of the CMP pad (e.g., how soft the pad is), other process parameters (e.g., the controlled pressure, the controlled rotational speed, etc.), and the slurry used during the process, CMP can result in removal of more material at an outer edge or perimeter of a surface being polished than near the center. More particularly, in some examples, the particular parameters used for the CMP process can be tuned so that the removal of material on the outer perimeter provides a relatively smooth transition (e.g., a rounded edge) between the top surface and the side surface. Accordingly, in some examples, such a CMP process is applied to individual chips that initially have a perimeter 522 on the back surface 510 defined by sharp or abrupt corners to produce rounded corners as shown in FIG. 9. The particular CMP parameters used to achieve a rounded bevel 904, as shown in FIG. 9, depends on the particular application and the desired radius of curvature to be produced. In some examples, to produce the rounded bevel 904, the CMP pad is relatively soft (e.g., a durometer Shore A range of 5 to 90 or Shore D of less than 6 to 40). The downforce of the pad can range from less than 0.5 psi to 5 psi with a rotational speed ranging from between 15 rpm and 150 rpm over a period of time ranging from a few tens of seconds (e.g., at least 20 second) up to a few minutes (e.g., up to 10 minutes). The slurry can use any suitable abrasives (e.g., ceria-base abrasives, glass base abrasives) and have any suitable pH (e.g., from 1 to 13). In some examples, the rounded bevel 904 can be achieved with a single pass with a single CMP pad. In other examples, multiple passes with the same or different CMP pads may be employed.

In the illustrated example, the rounded corners 902 defining the rounded bevel 904 have a radius of curvature that is smaller than the radius of curvature of the curved fillets 532 along the lateral edges 528 of the chip 900. In other examples, the rounded corners 902 have a radius of curvature that is approximately equal to the radius of curvature of the curved fillets 532. In other examples, the rounded corners 902 have a radius of curvature that is larger than the radius of curvature of the curved fillets 532.

In some examples, the perimeter 520 of the front surface 508 also includes a rounded bevel similar to the rounded bevel 904 along the perimeter 522 of the back surface 510. In some such examples, the radius of curvature of the rounded bevel surrounding the front surface 508 can be smaller, larger, or approximately the same size as the rounded bevel 904 and smaller, larger, or approximately the same size as the curved fillets 532. In some examples, the perimeter 520 of the front surface 508 is rounded (e.g., has a radius of curvature greater than 1 micrometer) while the perimeter 522 of the back surface 510 is defined by sharp or abrupt corners (e.g., has a radius of curvature less than 1 micrometer).

FIG. 10 illustrates another example IC chip 1000 constructed in accordance with teachings disclosed herein. The same reference numbers are used for the same or similar features shown in FIG. 10 as shown in FIGS. 5 and 9. Further, the description of such features provided above in connection with FIGS. 5 and 9 applies similarly to the corresponding features shown in FIG. 10. In the illustrated example of FIG. 10, the IC chip 1000 includes a rounded bevel 904 along the perimeter 522 of the front surface 510 similar to what is shown and described in FIG. 9. However, unlike the example shown in FIG. 9, the example IC chip 1000 of FIG. 10 includes sharp-cornered (e.g., abrupt-cornered) lateral intersections or edges 1002 between the lateral surfaces 512, 514, 516, 518 similar to the sharp-cornered (e.g., abrupt-cornered) lateral edges 126 shown in FIG. 1. In some examples, the perimeter 520 of the front surface 508 can also be defined by a rounded bevel in addition to or instead of the rounded bevel 904 associated with the front surface 510.

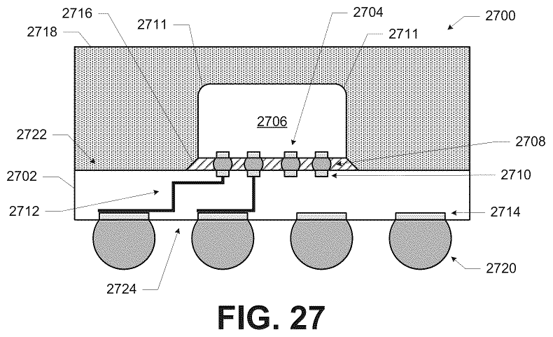

FIG. 11 is a cross-sectional view of an example IC package 1100 constructed in accordance with teachings disclosed herein. In this example, the IC package 1100 includes a base die 1102 (e.g., an IC chip) and two smaller dies 1104, 1106 (e.g., IC chips) mounted to the base die 1102. Each of the dies 1102, 1104, 1106 includes a bulk semiconductor substrate 502, a FEOL process area 504, and a BEOL process area 506 similar to the example chips 500, 806, 900, 1000 described above. In this example, the smaller dies 1104, 1106 are hybrid bonded (e.g., fusion bonded) to the base die 1102. That is, as shown in the illustrated example, the smaller dies 1104, 1106 include metal interconnects 1108 within the BEOL process area 506 that are electrically coupled with contact pads 1110 on the front surface 508 (e.g., a first outer surface) of the dies 1104, 1106. In this example, the contact pads 1110 are in direct contact with and electrically coupled (e.g., via fusion/hybrid bonds) to corresponding contacts on the front surface of the base die 1102. Teachings disclosed herein can be used on dies packaged and/or interconnected to other components in ways other than hybrid bonded interconnects. For example, semiconductors chiplets manufactured in accordance with teaching disclosed herein can be packaged using processes such as thermal compression bonding or capillary based mass reflow processes. In these cases, copper based bumps or micro-bumps act as the interconnects with or without solder. For instance, FIG. 27 illustrates an example die 2706 constructed in accordance with teachings disclosed herein incorporated into a flip package with contacts 2704 used to mount (e.g., via thermal compression bonding) to an underlying package substrate 2702. Other packaging arrangements and applications for teachings disclosed herein are also possible.

In this example, the smaller dies 1104, 1106 are surrounded (e.g., enclosed) by a dielectric material 1112 that is than covered by structural silicon 1114 that serves as a lid for the IC package 1100. In this example, the smaller dies 1104, 1106 are fabricated similar to the example IC chip 900 of FIG. 9 with a rounded bevel 904 along the perimeter 522 of the back surface 510 and curved fillets 532 (not visible from the cross-section shown) along lateral edges 528 of the dies 1104, 1106. The rounded bevel 904 and the curved fillets 532 serve to reduce (e.g., prevent) cracks from arising internally within the smaller dies 1104, 1106 and/or to reduce (e.g., prevent) cracks from arising in the dielectric material 1112 surrounding the smaller dies 1104, 1106.

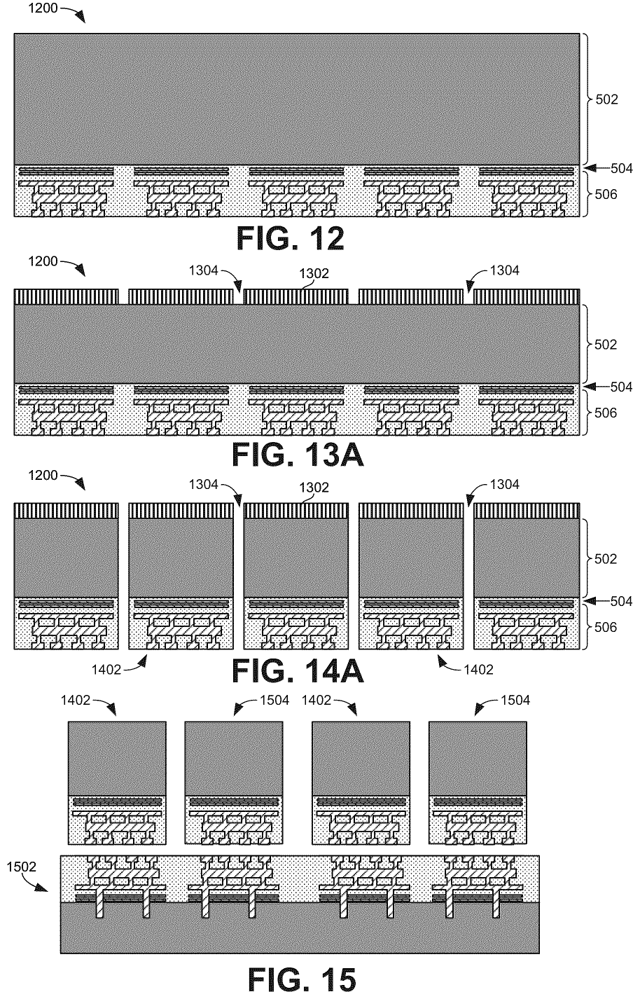

FIGS. 12-18 illustrate example stages during the fabrication process of the example IC package of FIG. 11. FIG. 12 illustrates an example wafer 1200 at the completion of the BEOL process. That is, the example wafer 1200 includes the BEOL process area 506 fabricated on the FEOL process area 504 that was fabricated on a bulk semiconductor substrate 502. In some examples, the wafer 1200 corresponds to the example wafer 200 of FIG. 6.

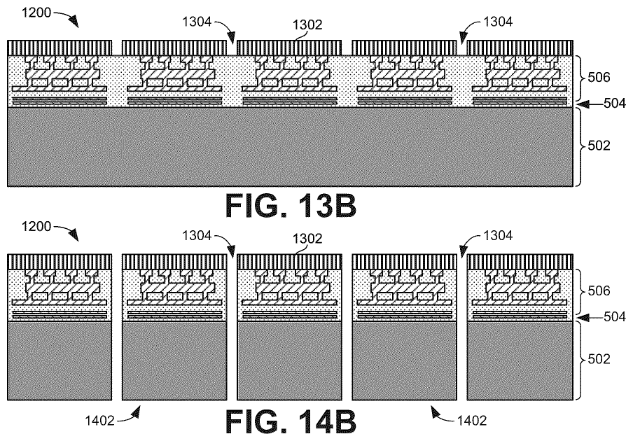

FIG. 13A represents the example wafer 1200 following a thinning (e.g., grinding) process to remove a portion of the bulk semiconductor substrate 102. Further, FIG. 13A illustrates an example mask 1302 (e.g., photoresist) that has been deposited on the bulk semiconductor substrate 502. At the stage of fabrication represented in FIG. 13A, the example mask 1302 has been lithographically patterned to define openings 1304 exposing portions of the underlying semiconductor substrate 502. In this example, the openings 1304 correspond to the etch regions 602, 618, 620 described above in connection with FIG. 6 to surround and enable the singulation of individual chips or dies. Thus, in this example, the openings 1304 define etch regions that have a rectangular shape with rounded corners. For purposes of simplicity, portions of the mask covering the portions 616 of the wafer between adjacent etch regions 602, as discussed above in connection with FIG. 6, have been omitted in the illustrated example of FIG. 13.

FIG. 14A represents the example wafer 1200 after singulation in which individual dies or chips 1402 are defined. In some examples, the chips 1402 correspond to any of the example dies or chips 500, 806, 900, 1000, 1104, 1106 described above. In this example, singulation is achieved without using a saw. Instead, singulation is achieved through an etching process that is controlled by the openings 1304 in the mask 1302. In some examples, the etching process is a plasma etching process. In some examples, a single etching process is implemented to cut through the entire wafer 1200. In other examples, a first etching process is used to cut through the semiconductor substrate 502 and a second etching process is used to cut through the dielectric material within the FEOL and BEOL process areas 504, 506. In some examples, the separate processes are implemented because of the different materials being etched away. However, in some such examples, the same mask 1302 can be used for both etching processes. As shown in the illustrated example, the etch regions (defined by the openings 1304) are located to extend through metal free zones to facilitate the etching process.

The mask 1302 is shown and described as being deposited on the semiconductor substrate 502 and the etching process extending first through the semiconductor substrate 502 and then through the FEOL and BEOL process areas 504, 506. However, in other examples, the wafer 1200 can be flipped over and the process implemented on the other side of the wafer 1200. This alternative process is represented by FIG. 13B and FIGS. 14B, which are identical to FIGS. 13A and 14A, respectively, except that the wafer 1200 has been flipped over. Thus, as shown in the illustrated example of FIGS. 13B and 14B, the mask 1302 is deposited and patterned on the BEOL process area 506 and the etching process cuts through the BEOL process area 506 first, followed by the FEOL process area 504, and then finishes with the semiconductor substrate 502. In some examples, different masks and associated etching processes can be applied to both sides of the wafer 1200.

The singulation of the wafer 1200 into individual chips 1402 shown in connection with FIGS. 13A, 13B, 14A, and 14B has been described primarily as being accomplished through a plasma etch. However, as mentioned above, there are other dicing techniques that can also achieve non-rectangular (e.g., arbitrary) shapes including the shapes disclosed herein that include rounded edges or fillets. For instance, in some examples, stealth dicing can be used. In some such examples, galvo-based laser ablation is initially used to ablate material (e.g., remove the dielectrics and/or metals from) along any desired path defining the shape for the chips 1402 (e.g., along the scribe lines) and then stealth dicing is implemented to complete the singulation process.

Following completion of the singulation process (via etching), the mask 1302 is removed. Thereafter, as represented in FIG. 15, the individual chips 1402 can be moved (e.g., via a pick-and-place machine) onto a separate substrate or wafer 1502. In this example, the wafer 1502 includes circuitry corresponding to the base die 1102 of FIG. 11. In some examples, different dies or chips 1504 from a different initial wafer (not shown) are positioned onto the wafer 1502 adjacent the chips 1402 singulated from the wafer 1200 of FIG. 12. Using known techniques, based on chips with sharp or abrupt corners for edges, the pick-and-place process can result in internal cracks developing within the chips 1402, 1504. However, by fabricating the chips 1402, 1504 with rounded edges, as disclosed herein, the likelihood of such cracks developing is significantly reduced because the mechanical stress points along the sharp or abrupt corners are eliminated. In this example, once positioned on the wafer 1502, the chips 1402, 1504 are mechanically coupled to the base wafer 1502 via hybrid bonding (e.g., via the application of compression and/or heat for a period of time). In other instances, the singulated chips 1402 can be bonded to the base wafer 1502 using thermal compression bonding or capillary mass reflow. In other instances, the chips 1402 can be bonded to a silicon carrier wafer using inorganic bonding material (e.g., fusion bonding) or to a silicon or glass carrier wafer using organic bonding materials (e.g., temporary bonding).

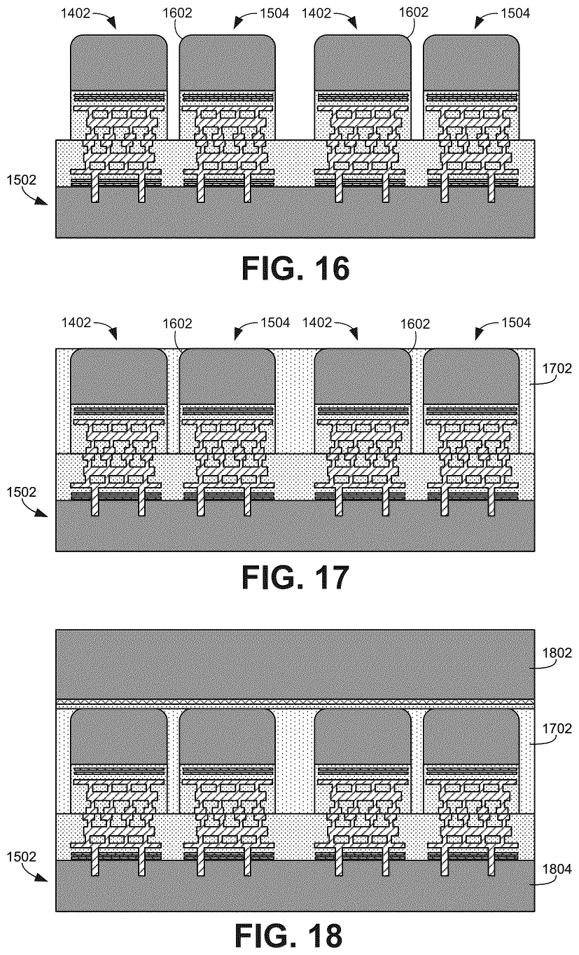

FIG. 16 represents the stage of fabrication after the chips 1402, 1504 on the base wafer 1502 have undergone chemical mechanical planarization (CMP). The CMP process involves grinding or polishing the top surface (e.g., the back surface 510) of the chips 1402, 1504 with a CMP pad. In some examples, the parameters of the CMP process are tuned to take off excess material along the outer edges or perimeters of the top surface of the chips to produce a rounded bevel 1602 similar to the rounded bevel 904 shown and described in connection with FIG. 9. This is made possible by having the individual chips 1402, 1504 spaced apart on the base wafer 1502 with gaps between the chips 1402, 1504, as shown in the illustrated example. The gaps between the chips during the CMP process enable the relatively soft CMP pad to press down into the gaps, thereby causing removal of material along the upper perimeter of the chips 1402, 1504 as discussed above.

FIG. 17 represents the stage of fabrication following the deposition of a dielectric material 1702 (e.g., corresponding to the dielectric material 1112 of FIG. 11) to surround the chips 1402, 1504 and to fill the gaps therebetween. In other instances, these gaps can be filled with an epoxy underfill material and/or an epoxy mold compound. The relatively sharp or abrupt corners of known chips provide stress points that can give rise to cracks within the dielectric material 1702. However, by fabricating the chips 1402, 1504 with rounded edges and a rounded upper perimeter, as disclosed herein, the likelihood of such cracks developing is significantly reduced because the sharp or abrupt corners and the associated mechanical stress points are eliminated.

FIG. 18 represents the stage of fabrication following the addition of a structural silicon 1802 on to the dielectric material 1702. After this stage of fabrication, the assembly can go through another singulation process to divide the wafer into individual packages (e.g., individual instances of the example IC package 1100 of FIG. 11). In some examples, this singulation process can be achieved using a saw as is commonly done today. In other examples, a mask can be applied and patterned to control a plasma etching process that extends through the entire assembly in a similar manner to what is described above in connection with FIGS. 13A and 14A and/or 13B and 14B. In some examples, after singulation, the individual IC package assemblies can be added to a temporary carrier and/or other suitable substrate to undergo another CMP process to round the outer edges (e.g., perimeter of the structural silicon 1802) and/or the semiconductor substrate 1804 of the base wafer 1502 in a similar manner to the process described above.

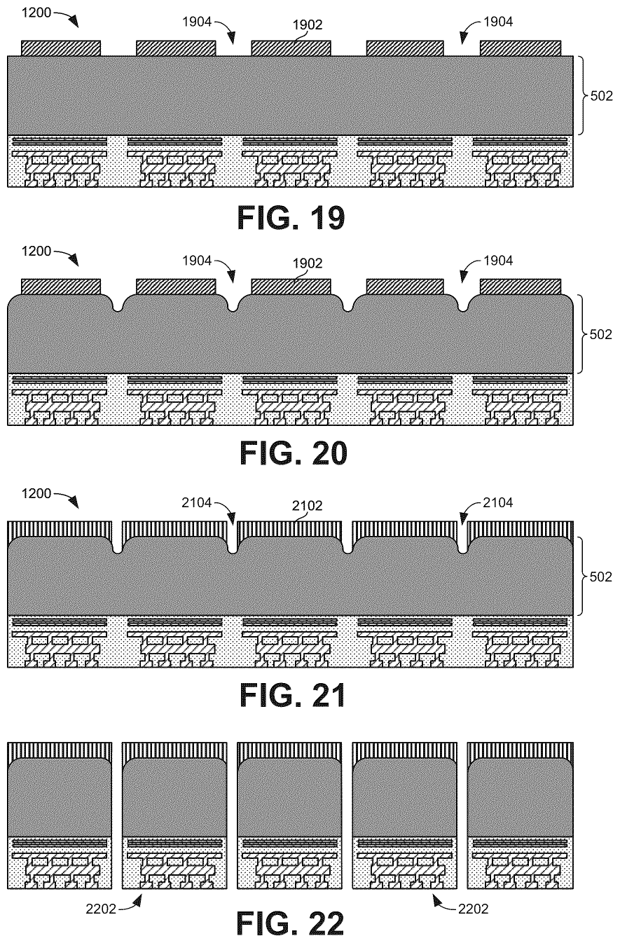

FIGS. 19-22 illustrate different stages in an alternative example fabrication process to produce a rounded bevel along a perimeter of the back surface of the chips. The example fabrication process begins with the same wafer 1200 shown in FIG. 12. FIG. 19 represents the example wafer 1200 following a thinning (e.g., grinding) process to remove a portion of the bulk semiconductor substrate 502. Further, FIG. 19 illustrates an example mask 1902 that has been deposited on the bulk semiconductor substrate 502. At the stage of fabrication represented in FIG. 13A, the example mask 1902 has been lithographically patterned to define openings 1904 exposing portions of the underlying semiconductor substrate 502. Thus, the stage of fabrication represented in FIG. 19 is similar to the stage of fabrication represented in FIG. 13A except that the openings 1904 of FIG. 19 are different than the openings 1304 of FIG. 13A. Specifically, in the illustrated example of FIG. 19, the openings 1904 are patterned to expose the region corresponding to the perimeter 522 of the back surface 510 of the chips to be produced.

FIG. 20 illustrates the example wafer 1200 after undergoing an etch process to remove some of the semiconductor substrate 502 exposed through the openings 1904 in the mask 1902. In this example, the etch process involves a biased (e.g., anisotropic) dry etch to produce an etch that is deeper near the middle of the openings 1904 and shallower towards the outer walls of the openings 1904 as shown in the illustrated example. By controlling the etch process it is possible to produce rounded corners along the perimeter of the individual chips before singulation has been implemented.

FIG. 21 illustrates the example wafer 1200 after removal of the mask 1902 and the addition of a second mask 2102. In some examples, the second mask 2102 is added without removing the first mask 1902. In the illustrated example, the second mask 2102 is similar to the mask 1302 discussed above in connection with FIG. 13A. That is, the mask 2102 of FIG. 21 is patterned to include openings 2104 that correspond to the etch regions 602, 618, 620 of FIG. 6 to facilitate singulation via a plasma etch. FIG. 22 illustrates the example wafer 1200 following the plasma etch that results in the singulation of individual chips 2202. In some examples, the second mask 2101 can be deposited and patterned on the front side of the example wafer 1200 in line with the process detailed in connection with FIGS. 13B and 14B. Once the chips 2202 have been singulated and the mask removed, the chips 2202 can be moved onto any suitable substrate such as the base wafer 1502 of FIG. 15. In this example, there is no need to implement the CMP process discussed above in connection with FIG. 16 because the rounded bevel 904 for the individual chips 2202 has already been created through the etching process previously implemented as described in connection with FIGS. 19-21.

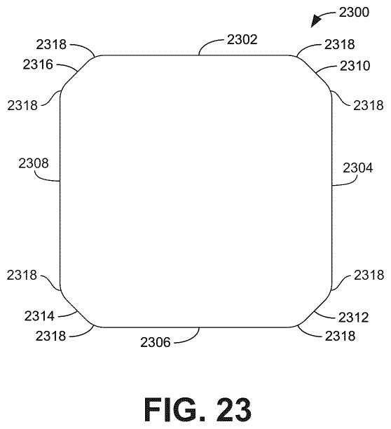

As discussed above, the example chips disclosed herein are not limited to having an external shape or footprint that is rectangular because the dicing of the chips from a wafer is based on plasma etching that can control the shape of the chips to any suitable shape with sides or lateral surfaces that may planar or curved and positioned at any suitable angle relative to other lateral surfaces of the chips. As a specific example, FIG. 23 illustrates a top view of example non-rectangular IC chip 2300 constructed in accordance with teachings disclosed herein. More particularly, the example IC chip 2300 is still generally rectangular with four primary lateral surfaces 2302, 2304, 2306, 2308. However, rather than adjacent ones of the primary lateral surfaces 2302, 2304, 2306, 2308 intersecting at a common lateral edge, in this example, the primary lateral surfaces 2302, 2304, 2306, 2308 are separated by lateral chamfers 2310, 2312, 2314, 2316 that extend at 45-degree angles relative to the adjacent primary lateral surfaces 2302, 2304, 2306, 2308. In other examples, the chamfers 2310, 2312, 2314, 2316 can extend at angles other than 45 degrees relative to the primary lateral surfaces 2302, 2304, 2306, 2308. With four primary lateral surfaces 2302, 2304, 2306, 2308 and four chamfers 2310, 2312, 2314, 2316, the example IC chip 2300 includes a total of eight lateral edges 2318. As shown in the illustrated examples, the lateral edges 2318 are rounded with a radius of curvature of at least 2 micrometers to reduce (e.g., prevent) the creation of stress points that can cause cracks as discussed above. In some examples, the top edge along the perimeter of the example IC chip 2300 can be defined by a relative sharp or abrupt corner similar to the top edge (e.g., the perimeter 522) of the IC chip 500 of FIG. 5. In other examples, the top edge along the perimeter of the example IC chip 2300 can be defined by a rounded corner similar to the rounded bevel 904 of the IC chip 900 of FIG. 9.

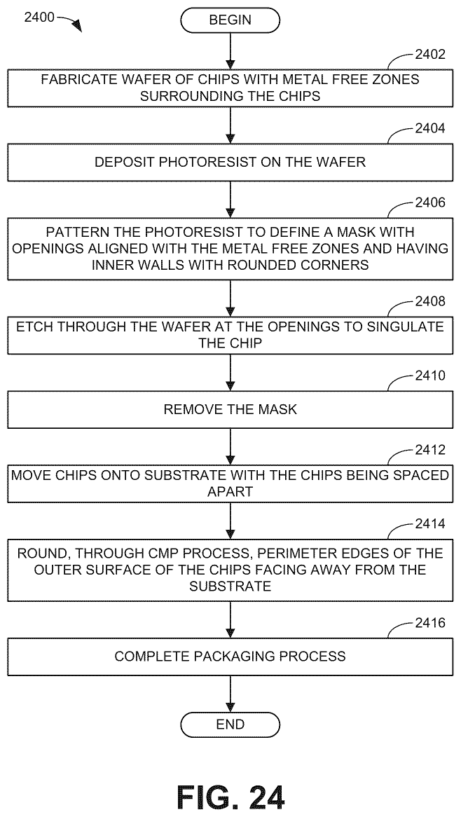

FIG. 24 is a flowchart representative of an example method 2400 that may be performed to fabricate an IC package based on the stages of fabrication represented in FIGS. 12-18. In some examples, some or all of the operations outlined in the example method of FIG. 24 are performed automatically by equipment that is programmed to perform the operations. Although the example method is described with reference to the flowchart illustrated in FIG. 24, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 2400 of FIG. 24 begins at block 2402 by fabricating a wafer of chips with metal free zones surrounding the chips. At block 2404, the example method includes depositing a photoresist on the wafer. At block 2406, the method includes patterning the photoresist to define a mask with openings aligned with the metal free zones and having inner walls with rounded corners. The radius of curvature of the rounded corners is to define the radius of curvature of the lateral edges of the chips once singulated. At block 2408, the example method includes etching through the wafer at the openings to singulate the chip. In some examples, the etching is accomplished by a single plasma etch. In other examples, multiple plasma etches are performed using the same mask. At block 2410, the example method includes removing the mask.

At block 2412, the example method includes moving the chips onto a substrate with the chips being spaced apart. That is, in some examples, the chips are reconstituted onto a wafer. In some examples, the substrate is a wafer that includes circuitry to be electrically coupled with the chips. In some examples, the chips are coupled to this circuitry via hybrid bonding (e.g., fusion bonding). In some examples, the substrate is a temporary wafer or carrier to support the chips during subsequent processing before the chips are moved onto a different substrate. At block 2414, the example method includes rounding, through a CMP process, the perimeter edges of the outer surface of the chips facing away from the substrate. In some examples, the outer surface of the chips corresponds to the back surface of the chips (e.g., the surface defined by the bulk semiconductor substrate). In other examples, the outer surface of the chips corresponds to the front surface of the chips (e.g., the surfacing containing the contacts coupled to the electrical interconnects inside the FEOL process area). In some examples, the chips are spaced apart on the substrate at block 2412 to facilitate the rounding of the perimeter edges at block 2414. In some examples, where it is acceptable to leave the perimeter edges being defined by sharp or abrupt corners (e.g., as shown in FIG. 5), blocks 2412 and 2414 may be omitted.

At block 2416, the example method includes completing the packaging process. What is involved in completing the packaging process depends on the type of IC package being fabricated. Any suitable processes now known or later developed can be implemented to complete this process. Thereafter, the example method of FIG. 24 ends.

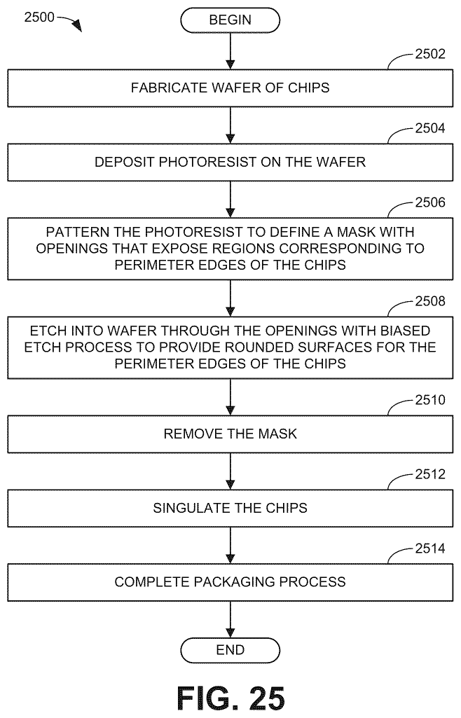

FIG. 25 is a flowchart representative of an example method 2500 that may be performed to fabricate an IC package based on the stages of fabrication represented in FIGS. 19-22. In some examples, some or all of the operations outlined in the example method of FIG. 25 are performed automatically by equipment that is programmed to perform the operations. Although the example method is described with reference to the flowchart illustrated in FIG. 25, many other methods may alternatively be used. For example, the order of execution of the blocks may be changed, and/or some of the blocks described may be combined, divided, re-arranged, omitted, eliminated, and/or implemented in any other way. Further, in some examples, additional processing operations can be performed before, between, and/or after any of the blocks represented in the illustrated example.

The example method 2500 of FIG. 25 begins at block 2502 by fabricating a wafer of chips. At block 2504, the example method includes depositing a photoresist on the wafer. At block 2506, the method includes patterning the photoresist to define a mask with openings that expose regions corresponding to perimeter edges of the chips. At block 2508, the example method includes etching into the wafer through the openings with a biased etch process to provide rounded surfaces for the perimeter edges of the chips. At block 2510, the example method includes removing the mask. At block 2512, the example method includes singulating the chips. In some examples, this is accomplished following the processed outlined above in connection with blocks 2404-2410 of FIG. 24 to produce chips with rounded lateral edges. In other examples, where the perimeter edges of the outer surface of the chip are to be rounded but the lateral edges can be defined by sharp or abrupt corners (e.g., as shown in FIG. 10), the singulation can be achieved using a saw. At block 2514, the example method includes completing the packaging process. What is involved in completing the packaging process depends on the type of IC package being fabricated. Any suitable processes now known or later developed can be implemented to complete this process. Thereafter, the example method of FIG. 25 ends.

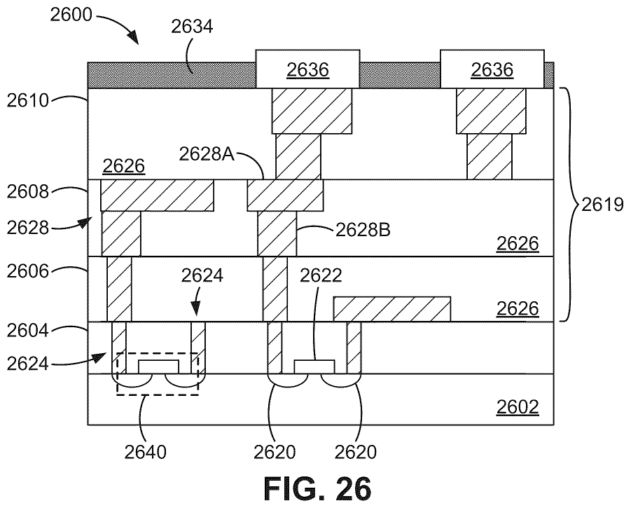

The example dies or chips 500, 806, 900, 1000, 1104, 1106, 1402, 1504, 2202 disclosed herein may be included in any suitable electronic component. FIGS. 26-29 illustrate various examples of apparatus that may include or be included in the dies or chips 500, 806, 900, 1000, 1104, 1106, 1402, 1504, 2202 disclosed herein.

FIG. 26 is a cross-sectional side view of an IC device 2600 that may be included in one or more dies or chips 500, 806, 900, 1000, 1104, 1106, 1402, 1504, 2202 disclosed herein. The IC device 2600 may be formed on a die substrate 2602 (e.g., the bulk semiconductor substrate 502). The die substrate 2602 may be a semiconductor substrate including semiconductor materials including, for example, n-type or p-type materials systems (or a combination of both). The die substrate 2602 may include, for example, a crystalline substrate formed using a bulk silicon or a silicon-on-insulator (SOI) substructure. In some examples, the die substrate 2602 may be formed using alternative materials, which may or may not be combined with silicon, that include but are not limited to germanium, indium antimonide, lead telluride, indium arsenide, indium phosphide, gallium arsenide, or gallium antimonide. Further materials classified as group II-VI, III-V, or IV may also be used to form the die substrate 2602. Although a few examples of materials from which the die substrate 2602 may be formed are described here, any material that may serve as a foundation for an IC device 2600 may be used.

The IC device 2600 may include one or more device layers 2604 disposed on and/or above the die substrate 2602. The device layer 2604 may include features of one or more transistors 2640 (e.g., metal oxide semiconductor field-effect transistors (MOSFETs)) formed on the die substrate 2602. The device layer 2604 may include, for example, one or more source and/or drain (S/D) regions 2620, a gate 2622 to control current flow between the S/D regions 2620, and one or more S/D contacts 2624 to route electrical signals to/from the S/D regions 2620. The transistors 2640 may include additional features not depicted for the sake of clarity, such as device isolation regions, gate contacts, and the like. The transistors 2640 are not limited to the type and configuration depicted in FIG. 26 and may include a wide variety of other types and/or configurations such as, for example, planar transistors, non-planar transistors, or a combination of both. Non-planar transistors may include FinFET transistors, such as double-gate transistors or tri-gate transistors, and wrap-around or all-around gate transistors, such as nanoribbon and nanowire transistors.

Each transistor 2640 may include a gate 2622 including a gate dielectric and a gate electrode. The gate dielectric may include one layer or a stack of layers. The one or more layers may include silicon oxide, silicon dioxide, silicon carbide, and/or a high-k dielectric material. The high-k dielectric material may include elements such as hafnium, silicon, oxygen, titanium, tantalum, lanthanum, aluminum, zirconium, barium, strontium, yttrium, lead, scandium, niobium, and/or zinc. Examples of high-k materials that may be used in the gate dielectric include, but are not limited to, hafnium oxide, hafnium silicon oxide, lanthanum oxide, lanthanum aluminum oxide, zirconium oxide, zirconium silicon oxide, tantalum oxide, titanium oxide, barium strontium titanium oxide, barium titanium oxide, strontium titanium oxide, yttrium oxide, aluminum oxide, lead scandium tantalum oxide, and/or lead zinc niobate. In some examples, an annealing process may be carried out on the gate dielectric to improve its quality when a high-k material is used.

The gate electrode may be formed on the gate dielectric and may include at least one p-type work function metal or n-type work function metal, depending on whether the transistor 2640 is to be a p-type metal oxide semiconductor (PMOS) or an n-type metal oxide semiconductor (NMOS) transistor. In some implementations, the gate electrode may include a stack of two or more metal layers, where one or more metal layers are work function metal layers and at least one metal layer is a fill metal layer. Further metal layers may be included, such as a barrier layer. For a PMOS transistor, metals that may be used for the gate electrode include, but are not limited to, ruthenium, palladium, platinum, cobalt, nickel, conductive metal oxides (e.g., ruthenium oxide), and/or any of the metals discussed below with reference to an NMOS transistor (e.g., for work function tuning). For an NMOS transistor, metals that may be used for the gate electrode include, but are not limited to, hafnium, zirconium, titanium, tantalum, aluminum, alloys of these metals, carbides of these metals (e.g., hafnium carbide, zirconium carbide, titanium carbide, tantalum carbide, and/or aluminum carbide), and/or any of the metals discussed above with reference to a PMOS transistor (e.g., for work function tuning).

In some examples, when viewed as a cross-section of the transistor 2640 along the source-channel-drain direction, the gate electrode may include a U-shaped structure that includes a bottom portion substantially parallel to the surface of the die substrate 2602 and two sidewall portions that are substantially perpendicular to the top surface of the die substrate 2602. In other examples, at least one of the metal layers that form the gate electrode may be a planar layer that is substantially parallel to the top surface of the die substrate 2602 and does not include sidewall portions substantially perpendicular to the top surface of the die substrate 2602. In other examples, the gate electrode may include a combination of U-shaped structures and/or planar, non-U-shaped structures. For example, the gate electrode may include one or more U-shaped metal layers formed atop one or more planar, non-U-shaped layers.

In some examples, a pair of sidewall spacers may be formed on opposing sides of the gate stack to bracket the gate stack. The sidewall spacers may be formed from materials such as silicon nitride, silicon oxide, silicon carbide, silicon nitride doped with carbon, and/or silicon oxynitride. Processes for forming sidewall spacers are well known in the art and generally include deposition and etching process operations. In some examples, a plurality of spacer pairs may be used; for instance, two pairs, three pairs, or four pairs of sidewall spacers may be formed on opposing sides of the gate stack.

The S/D regions 2620 may be formed within the die substrate 2602 adjacent to the gate 2622 of corresponding transistor(s) 2640. The S/D regions 2620 may be formed using an implantation/diffusion process or an etching/deposition process, for example. In the former process, dopants such as boron, aluminum, antimony, phosphorous, or arsenic may be ion-implanted into the die substrate 2602 to form the S/D regions 2620. An annealing process that activates the dopants and causes them to diffuse farther into the die substrate 2602 may follow the ion-implantation process. In the latter process, the die substrate 2602 may first be etched to form recesses at the locations of the S/D regions 2620. An epitaxial deposition process may then be carried out to fill the recesses with material that is used to fabricate the S/D regions 2620. In some implementations, the S/D regions 2620 may be fabricated using a silicon alloy such as silicon germanium or silicon carbide. In some examples, the epitaxially deposited silicon alloy may be doped in situ with dopants such as boron, arsenic, or phosphorous. In some examples, the S/D regions 2620 may be formed using one or more alternate semiconductor materials such as germanium or a group III-V material or alloy. In further examples, one or more layers of metal and/or metal alloys may be used to form the S/D regions 2620.

Electrical signals, such as power and/or input/output (I/O) signals, may be routed to and/or from the devices (e.g., transistors 2640) of the device layer 2604 through one or more interconnect layers disposed on the device layer 2604 (illustrated in FIG. 26 as interconnect layers 2606-2610). For example, electrically conductive features of the device layer 2604 (e.g., the gate 2622 and the S/D contacts 2624) may be electrically coupled with the interconnect structures 2628 of the interconnect layers 2606-2610. The one or more interconnect layers 2606-2610 may form a metallization stack (also referred to as an “ILD stack”) 2619 of the IC device 2600.

The interconnect structures 2628 may be arranged within the interconnect layers 2606-2610 to route electrical signals according to a wide variety of designs (in particular, the arrangement is not limited to the particular configuration of interconnect structures 2628 depicted in FIG. 26). Although a particular number of interconnect layers 2606-2610 is depicted in FIG. 26, examples of the present disclosure include IC devices having more or fewer interconnect layers than depicted.

In some examples, the interconnect structures 2628 may include lines 2628a and/or vias 2628b filled with an electrically conductive material such as a metal. The lines 2628a may be arranged to route electrical signals in a direction of a plane that is substantially parallel with a surface of the die substrate 2602 upon which the device layer 2604 is formed. For example, the lines 2628a may route electrical signals in a direction in and/or out of the page from the perspective of FIG. 26. The vias 2628b may be arranged to route electrical signals in a direction of a plane that is substantially perpendicular to the surface of the die substrate 2602 upon which the device layer 2604 is formed. In some examples, the vias 2628b may electrically couple lines 2628a of different interconnect layers 2606-2610 together.

The interconnect layers 2606-2610 may include a dielectric material 2626 disposed between the interconnect structures 2628, as shown in FIG. 26. In some examples, the dielectric material 2626 disposed between the interconnect structures 2628 in different ones of the interconnect layers 2606-2610 may have different compositions; in other examples, the composition of the dielectric material 2626 between different interconnect layers 2606-2610 may be the same.

A first interconnect layer 2606 (referred to as Metal 1 or “M1”) may be formed directly on the device layer 2604. In some examples, the first interconnect layer 2606 may include lines 2628a and/or vias 2628b, as shown. The lines 2628a of the first interconnect layer 2606 may be coupled with contacts (e.g., the S/D contacts 2624) of the device layer 2604.

A second interconnect layer 2608 (referred to as Metal 2 or “M2”) may be formed directly on the first interconnect layer 2606. In some examples, the second interconnect layer 2608 may include vias 2628b to couple the lines 2628a of the second interconnect layer 2608 with the lines 2628a of the first interconnect layer 2606. Although the lines 2628a and the vias 2628b are structurally delineated with a line within each interconnect layer (e.g., within the second interconnect layer 2608) for the sake of clarity, the lines 2628a and the vias 2628b may be structurally and/or materially contiguous (e.g., simultaneously filled during a dual-damascene process) in some examples.

A third interconnect layer 2610 (referred to as Metal 3 or “M3”) (and additional interconnect layers, as desired) may be formed in succession on the second interconnect layer 2608 according to similar techniques and/or configurations described in connection with the second interconnect layer 2608 or the first interconnect layer 2606. In some examples, the interconnect layers that are “higher up” in the metallization stack 2619 in the IC device 2600 (i.e., further away from the device layer 2604) may be thicker.

The IC device 2600 may include a solder resist material 2634 (e.g., polyimide or similar material) and one or more conductive contacts 2636 formed on the interconnect layers 2606-2610. In FIG. 26, the conductive contacts 2636 are illustrated as taking the form of bond pads. The conductive contacts 2636 may be electrically coupled with the interconnect structures 2628 and configured to route the electrical signals of the transistor(s) 2640 to other external devices. For example, solder bonds may be formed on the one or more conductive contacts 2636 to mechanically and/or electrically couple a chip including the IC device 2600 with another component (e.g., a circuit board). The IC device 2600 may include additional or alternate structures to route the electrical signals from the interconnect layers 2606-2610; for example, the conductive contacts 2636 may include other analogous features (e.g., posts) that route the electrical signals to external components.

FIG. 27 is a cross-sectional view of an example IC package 2700 that may include one or more of the example dies or chips 500, 806, 900, 1000, 1104, 1106, 1402, 1504, 2202 disclosed herein. The package substrate 2702 may include a dielectric material, and may have conductive pathways extending through the dielectric material between upper and lower faces 2722, 2724, and/or between different locations on the upper face 2722, and/or between different locations on the lower face 2724. These conductive pathways may take the form of any of the interconnects 2628 discussed above with reference to FIG. 26.

The IC package 2700 may include a die 2706 coupled to the package substrate 2702 via conductive contacts 2704 of the die 2706, first-level interconnects 2708, and conductive contacts 2710 of the package substrate 2702. As shown in the illustrated example, the die 2706 includes rounded edges 2711. In some examples, the rounded edges 2711 correspond to rounded lateral edges between lateral surfaces. Additionally or alternatively, in some examples, the rounded edges 2711 include rounded perimeter edges. The conductive contacts 2710 may be coupled to conductive pathways 2712 through the package substrate 2702, allowing circuitry within the die 2706 to electrically couple to various ones of the conductive contacts 2714. The first-level interconnects 2708 illustrated in FIG. 27 are solder bumps, but any suitable first-level interconnects 2708 may be used. As used herein, a “conductive contact” refers to a portion of conductive material (e.g., metal) serving as an electrical interface between different components. Conductive contacts may be recessed in, flush with, or extending away from a surface of a component, and may take any suitable form (e.g., a conductive pad or socket).

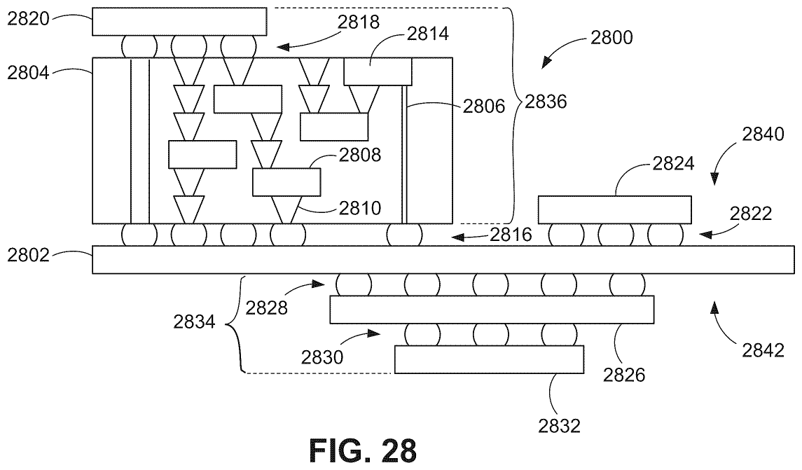

In some examples, an underfill material 2716 may be disposed between the die 2706 and the package substrate 2702 around the first-level interconnects 2708, and/or a mold compound 2718 may be disposed around the die 2706 and in contact with the package substrate 2702. In some examples, the underfill material 2716 may be the same as the mold compound 2718. Example materials that may be used for the underfill material 2716 and the mold compound 2718 are epoxy mold materials, as suitable. Second-level interconnects 2720 may be coupled to the conductive contacts 2714. The second-level interconnects 2720 illustrated in FIG. 27 are solder balls (e.g., for a ball grid array arrangement), but any suitable second-level interconnects 2720 may be used (e.g., pins in a pin grid array arrangement or lands in a land grid array arrangement). The second-level interconnects 2720 may be used to couple the IC package 2700 to another component, such as a circuit board (e.g., a motherboard), an interposer, or another IC package, as known in the art and as discussed below with reference to FIG. 28.

In FIG. 27, the IC package 2700 is a flip chip package. However, other package architectures may be used. For example, the IC package 2700 may be a ball grid array (BGA) package, such as an embedded wafer-level ball grid array (eWLB) package. In another example, the IC package 2700 may be a wafer-level chip scale package (WLCSP) or a panel fanout (FO) package. Although a single die 2706 is illustrated in the IC package 2700 of FIG. 27, an IC package 2700 may include multiple dies 2706 (e.g., with one or more corresponding to any one of the example dies or chips 500, 806, 900, 1000, 1104, 1106, 1402, 1504, 2202 disclosed herein). An IC package 2700 may include additional passive components, such as surface-mount resistors, capacitors, and/or inductors disposed on the first face 2722 or the second face 2724 of the package substrate 2702. More generally, an IC package 2700 may include any other active and/or passive components known in the art.

FIG. 28 is a cross-sectional side view of an IC device assembly 2800 that may include one or more of the example dies or chips 500, 806, 900, 1000, 1104, 1106, 1402, 1504, 2202 disclosed herein. The IC device assembly 2800 includes a number of components disposed on a circuit board 2802 (which may be, for example, a motherboard). The IC device assembly 2800 includes components disposed on a first face 2840 of the circuit board 2802 and an opposing second face 2842 of the circuit board 2802; generally, components may be disposed on one or both faces 2840 and 2842.

In some examples, the circuit board 2802 may be a printed circuit board (PCB) including multiple metal layers separated from one another by layers of dielectric material and interconnected by electrically conductive vias. Any one or more of the metal layers may be formed in a desired circuit pattern to route electrical signals (optionally in conjunction with other metal layers) between the components coupled to the circuit board 2802. In other examples, the circuit board 2802 may be a non-PCB substrate.

The IC device assembly 2800 illustrated in FIG. 28 includes a package-on-interposer structure 2836 coupled to the first face 2840 of the circuit board 2802 by coupling components 2816. The coupling components 2816 may electrically and mechanically couple the package-on-interposer structure 2836 to the circuit board 2802, and may include solder balls (as shown in FIG. 28), male and female portions of a socket, an adhesive, an underfill material, and/or any other suitable electrical and/or mechanical coupling structure.

The package-on-interposer structure 2836 may include an IC package 2820 coupled to an interposer 2804 by coupling components 2818. The coupling components 2818 may take any suitable form for the application, such as the forms discussed above with reference to the coupling components 2816. Although a single IC package 2820 is shown in FIG. 28, multiple IC packages may be coupled to the interposer 2804; indeed, additional interposers may be coupled to the interposer 2804. The interposer 2804 may provide an intervening substrate used to bridge the circuit board 2802 and the IC package 2820. The IC package 2820 may be or include, for example, a die (e.g., any one of the example dies or chips 500, 806, 900, 1000, 1104, 1106, 1402, 1504, 2202 disclosed herein), an IC device (e.g., the IC device 2600 of FIG. 26), or any other suitable component. Generally, the interposer 2804 may spread a connection to a wider pitch or reroute a connection to a different connection. For example, the interposer 2804 may couple the IC package 2820 (e.g., a die) to a set of BGA conductive contacts of the coupling components 2816 for coupling to the circuit board 2802. In the example illustrated in FIG. 28, the IC package 2820 and the circuit board 2802 are attached to opposing sides of the interposer 2804; in other examples, the IC package 2820 and the circuit board 2802 may be attached to a same side of the interposer 2804. In some examples, three or more components may be interconnected by way of the interposer 2804.

In some examples, the interposer 2804 may be formed as a PCB, including multiple metal layers separated from one another by layers of dielectric material and interconnected by electrically conductive vias. In some examples, the interposer 2804 may be formed of an epoxy resin, a fiberglass-reinforced epoxy resin, an epoxy resin with inorganic fillers, a ceramic material, or a polymer material such as polyimide. In some examples, the interposer 2804 may be formed of alternate rigid or flexible materials that may include the same materials described above for use in a semiconductor substrate, such as silicon, germanium, and other group III-V and group IV materials. The interposer 2804 may include metal interconnects 2808 and vias 2810, including but not limited to through-silicon vias (TSVs) 2806. The interposer 2804 may further include embedded devices 2814, including both passive and active devices. Such devices may include, but are not limited to, capacitors, decoupling capacitors, resistors, inductors, fuses, diodes, transformers, sensors, electrostatic discharge (ESD) devices, and memory devices. More complex devices such as radio frequency devices, power amplifiers, power management devices, antennas, arrays, sensors, and microelectromechanical systems (MEMS) devices may also be formed on the interposer 2804. The package-on-interposer structure 2836 may take the form of any of the package-on-interposer structures known in the art.

The IC device assembly 2800 may include an IC package 2824 coupled to the first face 2840 of the circuit board 2802 by coupling components 2822. The coupling components 2822 may take the form of any of the examples discussed above with reference to the coupling components 2816, and the IC package 2824 may take the form of any of the examples discussed above with reference to the IC package 2820.

The IC device assembly 2800 illustrated in FIG. 28 includes a package-on-package structure 2834 coupled to the second face 2842 of the circuit board 2802 by coupling components 2828. The package-on-package structure 2834 may include a first IC package 2826 and a second IC package 2832 coupled together by coupling components 2830 such that the first IC package 2826 is disposed between the circuit board 2802 and the second IC package 2832. The coupling components 2828, 2830 may take the form of any of the examples of the coupling components 2816 discussed above, and the IC packages 2826, 2832 may take the form of any of the examples of the IC package 2820 discussed above. The package-on-package structure 2834 may be configured in accordance with any of the package-on-package structures known in the art.

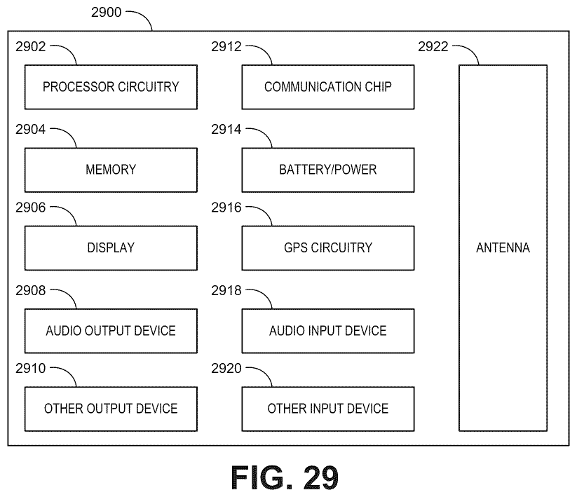

FIG. 29 is a block diagram of an example electrical device 2900 that may include one or more of the example dies or chips 500, 806, 900, 1000, 1104, 1106, 1402, 1504, 2202 disclosed herein. For example, any suitable ones of the components of the electrical device 2900 may include one or more of the device assemblies 2800, IC devices 2600, or the dies or chips 500, 806, 900, 1000, 1104, 1106, 1402, 1504, 2202 disclosed herein disclosed herein. A number of components are illustrated in FIG. 29 as included in the electrical device 2900, but any one or more of these components may be omitted or duplicated, as suitable for the application. In some examples, some or all of the components included in the electrical device 2900 may be attached to one or more motherboards. In some examples, some or all of these components are fabricated onto a single system-on-a-chip (SoC) die.

Additionally, in various examples, the electrical device 2900 may not include one or more of the components illustrated in FIG. 29, but the electrical device 2900 may include interface circuitry for coupling to the one or more components. For example, the electrical device 2900 may not include a display 2906, but may include display interface circuitry (e.g., a connector and driver circuitry) to which a display 2906 may be coupled. In another set of examples, the electrical device 2900 may not include an audio input device 2918 (e.g., microphone) or an audio output device 2908 (e.g., a speaker, a headset, earbuds, etc.), but may include audio input or output device interface circuitry (e.g., connectors and supporting circuitry) to which an audio input device 2918 or audio output device 2908 may be coupled.

The electrical device 2900 may include programmable circuitry 2902 (e.g., one or more processing devices). The programmable circuitry 2902 may include one or more digital signal processors (DSPs), application-specific integrated circuits (ASICs), central processing units (CPUs), graphics processing units (GPUs), cryptoprocessors (specialized processors that execute cryptographic algorithms within hardware), server processors, or any other suitable processing devices. The electrical device 2900 may include a memory 2904, which may itself include one or more memory devices such as volatile memory (e.g., dynamic random access memory (DRAM)), nonvolatile memory (e.g., read-only memory (ROM)), flash memory, solid state memory, and/or a hard drive. In some examples, the memory 2904 may include memory that shares a die with the programmable circuitry 2902. This memory may be used as cache memory and may include embedded dynamic random access memory (eDRAM) or spin transfer torque magnetic random access memory (STT-MRAM).

In some examples, the electrical device 2900 may include a communication chip 2912 (e.g., one or more communication chips). For example, the communication chip 2912 may be configured for managing wireless communications for the transfer of data to and from the electrical device 2900. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some examples they might not.

The communication chip 2912 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultra mobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. The communication chip 2912 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. The communication chip 2912 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). The communication chip 2912 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. The communication chip 2912 may operate in accordance with other wireless protocols in other examples. The electrical device 2900 may include an antenna 2922 to facilitate wireless communications and/or to receive other wireless communications (such as AM or FM radio transmissions).

In some examples, the communication chip 2912 may manage wired communications, such as electrical, optical, or any other suitable communication protocols (e.g., the Ethernet). As noted above, the communication chip 2912 may include multiple communication chips. For instance, a first communication chip 2912 may be dedicated to shorter-range wireless communications such as Wi-Fi or Bluetooth, and a second communication chip 2912 may be dedicated to longer-range wireless communications such as global positioning system (GPS), EDGE, GPRS, CDMA, WiMAX, LTE, EV-DO, or others. In some examples, a first communication chip 2912 may be dedicated to wireless communications, and a second communication chip 2912 may be dedicated to wired communications.

The electrical device 2900 may include battery/power circuitry 2914 associated with a power source. The battery/power circuitry 2914 may include one or more energy storage devices (e.g., batteries or capacitors) and/or circuitry for coupling components of the electrical device 2900 to an energy source separate from the electrical device 2900 (e.g., AC line power).

The electrical device 2900 may include a display 2906 (or corresponding interface circuitry, as discussed above). The display 2906 may include any visual indicators, such as a heads-up display, a computer monitor, a projector, a touchscreen display, a liquid crystal display (LCD), a light-emitting diode display, or a flat panel display.

The electrical device 2900 may include an audio output device 2908 (or corresponding interface circuitry, as discussed above). The audio output device 2908 may include any device that generates an audible indicator, such as speakers, headsets, or earbuds.

The electrical device 2900 may include an audio input device 2918 (or corresponding interface circuitry, as discussed above). The audio input device 2918 may include any device that generates a signal representative of a sound, such as microphones, microphone arrays, or digital instruments (e.g., instruments having a musical instrument digital interface (MIDI) output).

The electrical device 2900 may include GPS circuitry 2916. The GPS circuitry 2916 may be in communication with a satellite-based system and may receive a location of the electrical device 2900, as known in the art.

The electrical device 2900 may include any other output device 2910 (or corresponding interface circuitry, as discussed above). Examples of the other output device 2910 may include an audio codec, a video codec, a printer, a wired or wireless transmitter for providing information to other devices, or an additional storage device.

The electrical device 2900 may include any other input device 2920 (or corresponding interface circuitry, as discussed above). Examples of the other input device 2920 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

The electrical device 2900 may have any desired form factor, such as a hand-held or mobile electrical device (e.g., a cell phone, a smart phone, a mobile internet device, a music player, a tablet computer, a laptop computer, a netbook computer, an ultrabook computer, a personal digital assistant (PDA), an ultra mobile personal computer, etc.), a desktop electrical device, a server or other networked computing component, a printer, a scanner, a monitor, a set-top box, an entertainment control unit, a vehicle control unit, a digital camera, a digital video recorder, or a wearable electrical device. In some examples, the electrical device 2900 may be any other electronic device that processes data.

“Including” and “comprising” (and all forms and tenses thereof) are used herein to be open ended terms. Thus, whenever a claim employs any form of “include” or “comprise” (e.g., comprises, includes, comprising, including, having, etc.) as a preamble or within a claim recitation of any kind, it is to be understood that additional elements, terms, etc., may be present without falling outside the scope of the corresponding claim or recitation. As used herein, when the phrase “at least” is used as the transition term in, for example, a preamble of a claim, it is open-ended in the same manner as the term “comprising” and “including” are open ended. The term “and/or” when used, for example, in a form such as A, B, and/or C refers to any combination or subset of A, B, C such as (1) A alone, (2) B alone, (3) C alone, (4) A with B, (5) A with C, (6) B with C, or (7) A with B and with C. As used herein in the context of describing structures, components, items, objects and/or things, the phrase “at least one of A and B” is intended to refer to implementations including any of (1) at least one A, (2) at least one B, or (3) at least one A and at least one B. Similarly, as used herein in the context of describing structures, components, items, objects and/or things, the phrase “at least one of A or B” is intended to refer to implementations including any of (1) at least one A, (2) at least one B, or (3) at least one A and at least one B. As used herein in the context of describing the performance or execution of processes, instructions, actions, activities, etc., the phrase “at least one of A and B” is intended to refer to implementations including any of (1) at least one A, (2) at least one B, or (3) at least one A and at least one B. Similarly, as used herein in the context of describing the performance or execution of processes, instructions, actions, activities, etc., the phrase “at least one of A or B” is intended to refer to implementations including any of (1) at least one A, (2) at least one B, or (3) at least one A and at least one B.

As used herein, singular references (e.g., “a”, “an”, “first”, “second”, etc.) do not exclude a plurality. The term “a” or “an” object, as used herein, refers to one or more of that object. The terms “a” (or “an”), “one or more”, and “at least one” are used interchangeably herein. Furthermore, although individually listed, a plurality of means, elements, or actions may be implemented by, e.g., the same entity or object. Additionally, although individual features may be included in different examples or claims, these may possibly be combined, and the inclusion in different examples or claims does not imply that a combination of features is not feasible and/or advantageous.

As used herein, unless otherwise stated, the term “above” describes the relationship of two parts relative to Earth. A first part is above a second part, if the second part has at least one part between Earth and the first part. Likewise, as used herein, a first part is “below” a second part when the first part is closer to the Earth than the second part. As noted above, a first part can be above or below a second part with one or more of: other parts therebetween, without other parts therebetween, with the first and second parts touching, or without the first and second parts being in direct contact with one another.

Notwithstanding the foregoing, in the case of referencing a semiconductor device (e.g., a transistor), a semiconductor die containing a semiconductor device, and/or an integrated circuit (IC) package containing a semiconductor die during fabrication or manufacturing, “above” is not with reference to Earth, but instead is with reference to an underlying substrate on which relevant components are fabricated, assembled, mounted, supported, or otherwise provided. Thus, as used herein and unless otherwise stated or implied from the context, a first component within a semiconductor die (e.g., a transistor or other semiconductor device) is “above” a second component within the semiconductor die when the first component is farther away from a substrate (e.g., a semiconductor wafer) during fabrication/manufacturing than the second component on which the two components are fabricated or otherwise provided. Similarly, unless otherwise stated or implied from the context, a first component within an IC package (e.g., a semiconductor die) is “above” a second component within the IC package during fabrication when the first component is farther away from a printed circuit board (PCB) to which the IC package is to be mounted or attached. It is to be understood that semiconductor devices are often used in orientation different than their orientation during fabrication. Thus, when referring to a semiconductor device (e.g., a transistor), a semiconductor die containing a semiconductor device, and/or an integrated circuit (IC) package containing a semiconductor die during use, the definition of “above” in the preceding paragraph (i.e., the term “above” describes the relationship of two parts relative to Earth) will likely govern based on the usage context.

As used in this patent, stating that any part (e.g., a layer, film, area, region, or plate) is in any way on (e.g., positioned on, located on, disposed on, or formed on, etc.) another part, indicates that the referenced part is either in contact with the other part, or that the referenced part is above the other part with one or more intermediate part(s) located therebetween.

As used herein, connection references (e.g., attached, coupled, connected, and joined) may include intermediate members between the elements referenced by the connection reference and/or relative movement between those elements unless otherwise indicated. As such, connection references do not necessarily infer that two elements are directly connected and/or in fixed relation to each other. As used herein, stating that any part is in “contact” with another part is defined to mean that there is no intermediate part between the two parts.

Unless specifically stated otherwise, descriptors such as “first,” “second,” “third,” etc., are used herein without imputing or otherwise indicating any meaning of priority, physical order, arrangement in a list, and/or ordering in any way, but are merely used as labels and/or arbitrary names to distinguish elements for ease of understanding the disclosed examples. In some examples, the descriptor “first” may be used to refer to an element in the detailed description, while the same element may be referred to in a claim with a different descriptor such as “second” or “third.” In such instances, it should be understood that such descriptors are used merely for identifying those elements distinctly within the context of the discussion (e.g., within a claim) in which the elements might, for example, otherwise share a same name.

As used herein, “approximately” and “about” modify their subjects/values to recognize the potential presence of variations that occur in real world applications. For example, “approximately” and “about” may modify dimensions that may not be exact due to manufacturing tolerances and/or other real world imperfections as will be understood by persons of ordinary skill in the art. For example, “approximately” and “about” may indicate such dimensions may be within a tolerance range of +/−10% unless otherwise specified herein.

As used herein, the phrase “in communication,” including variations thereof, encompasses direct communication and/or indirect communication through one or more intermediary components, and does not require direct physical (e.g., wired) communication and/or constant communication, but rather additionally includes selective communication at periodic intervals, scheduled intervals, aperiodic intervals, and/or one-time events.

As used herein, “programmable circuitry” is defined to include (i) one or more special purpose electrical circuits (e.g., an application specific circuit (ASIC)) structured to perform specific operation(s) and including one or more semiconductor-based logic devices (e.g., electrical hardware implemented by one or more transistors), and/or (ii) one or more general purpose semiconductor-based electrical circuits programmable with instructions to perform specific functions(s) and/or operation(s) and including one or more semiconductor-based logic devices (e.g., electrical hardware implemented by one or more transistors). Examples of programmable circuitry include programmable microprocessors such as Central Processor Units (CPUs) that may execute first instructions to perform one or more operations and/or functions, Field Programmable Gate Arrays (FPGAs) that may be programmed with second instructions to cause configuration and/or structuring of the FPGAs to instantiate one or more operations and/or functions corresponding to the first instructions, Graphics Processor Units (GPUs) that may execute first instructions to perform one or more operations and/or functions, Digital Signal Processors (DSPs) that may execute first instructions to perform one or more operations and/or functions, XPUs, Network Processing Units (NPUs) one or more microcontrollers that may execute first instructions to perform one or more operations and/or functions and/or integrated circuits such as Application Specific Integrated Circuits (ASICs). For example, an XPU may be implemented by a heterogeneous computing system including multiple types of programmable circuitry (e.g., one or more FPGAs, one or more CPUs, one or more GPUs, one or more NPUs, one or more DSPs, etc., and/or any combination(s) thereof), and orchestration technology (e.g., application programming interface(s) (API(s)) that may assign computing task(s) to whichever one(s) of the multiple types of programmable circuitry is/are suited and available to perform the computing task(s).

As used herein integrated circuit/circuitry is defined as one or more semiconductor packages containing one or more circuit elements such as transistors, capacitors, inductors, resistors, current paths, diodes, etc. For example, an integrated circuit may be implemented as one or more of an ASIC, an FPGA, a chip, a microchip, programmable circuitry, a semiconductor substrate coupling multiple circuit elements, a system on chip (SoC), etc.

From the foregoing, it will be appreciated that example systems, apparatus, articles of manufacture, and methods have been disclosed that reduce the formation of cracks within IC chips or dies and/or reduces the formation of cracks in materials surrounding IC chips or dies in IC packages. Specifically, cracks are known to form from the high stress points created by the sharp-cornered (e.g., abrupt-cornered) edges of known IC chips. Examples disclosed herein avoid this problem by fabricating IC chips with rounded or curved edges and/or corners that provide smooth (e.g., curved) transitions between different surfaces of the chips.

Further examples and combinations thereof include the following:

Example 1 includes a semiconductor chip comprising a front surface, a back surface opposite the front surface, a first lateral surface extending between the front surface and the back surface, a second lateral surface extending between the front surface and the back surface, and a curved fillet at an intersection between the first lateral surface and the second lateral surface.

Example 2 includes the semiconductor chip of example 1, wherein the curved fillet has a radius of curvature of at least 5 micrometers.

Example 3 includes the semiconductor chip of any one of examples 1 or 2, wherein the curved fillet extends a full distance of a length of the intersection between the first lateral surface and the second lateral surface.

Example 4 includes the semiconductor chip of any one of examples 1-3, wherein the curved fillet is a first curved fillet, the semiconductor chip further including a third lateral surface between the front surface and the back surface, the third lateral surface opposite the first lateral surface, a fourth lateral surface between the front surface and the back surface, the fourth lateral surface opposite the second lateral surface, a second curved fillet at an intersection between the second lateral surface and the third lateral surface, a third curved fillet at an intersection between the third lateral surface and the fourth lateral surface, and a fourth curved fillet at an intersection between the fourth lateral surface and the first lateral surface.

Example 5 includes the semiconductor chip of any one of examples 1-4, further including a rounded edge along a length of an intersection between the back surface and the first lateral surface.

Example 6 includes the semiconductor chip of example 5, wherein the rounded edge has a first radius of curvature and the curved fillet has a second radius of curvature, the first radius of curvature smaller than the second radius of curvature.

Example 7 includes the semiconductor chip of any one of examples 5 or 6, wherein the rounded edge extends around a perimeter of the back surface.

Example 8 includes an integrated circuit package comprising a substrate, and a semiconductor die carried by the substrate, the semiconductor die having a footprint exhibiting a polygonal shape with rounded corners.

Example 9 includes the integrated circuit package of example 8, wherein the semiconductor die includes a first side facing the substrate, a second side opposite the first side, and lateral surfaces between the first side and the second side, the lateral surfaces defining the polygonal shape of the footprint of the semiconductor die.

Example 10 includes the integrated circuit package of any one of examples 8 or 9, wherein the polygonal shape corresponds to a rectangle.

Example 11 includes the integrated circuit package of any one of examples 8-10, wherein none of the rounded corners have a radius of curvature less than 2 micrometers.

Example 12 includes the integrated circuit package of any one of examples 8-11, wherein the semiconductor die includes a first side facing the substrate, and a second side opposite the first side, a rounded bevel along a perimeter of the second side of the semiconductor die.

Example 13 includes the integrated circuit package of example 12, wherein the semiconductor die is a first semiconductor die, the integrated circuit package including a second semiconductor die carried by the substrate adjacent the first semiconductor die, and a dielectric material between the first semiconductor die and the second semiconductor die, the dielectric material in contact with and extending around the rounded bevel.

Example 14 includes the integrated circuit package of any one of examples 8-13, wherein the semiconductor die is fusion bonded to the substrate.

Example 15 includes an apparatus comprising a substrate, and a semiconductor chip coupled to the substrate, the semiconductor chip including a first surface facing the substrate and a second surface facing away from the substrate, the semiconductor chip including a sidewall around a perimeter of the semiconductor chip between the first surface and the second surface, the sidewall devoid of abrupt corners between different segments of the sidewall, the different segments of the sidewall angled relative to one another.

Example 16 includes the apparatus of example 15, including rounded corners between the different segments of the sidewall, ones of the rounded corners including a radius of curvature of at least 5 micrometers.

Example 17 includes the apparatus of any one of examples 15 or 16, wherein the different segments correspond to different planar surfaces of the sidewall.

Example 18 includes the apparatus of any one of examples 15-17, wherein the semiconductor chip includes a rounded bevel at an interface of the second surface and the sidewall.

Example 19 includes the apparatus of any one of examples 15-18, wherein the semiconductor chip is hybrid bonded to the substrate.

Example 20 includes the apparatus of any one of examples 15-19, further including at least one of a power source, a keyboard, or a display.

The following claims are hereby incorporated into this Detailed Description by this reference. Although certain example systems, apparatus, articles of manufacture, and methods have been disclosed herein, the scope of coverage of this patent is not limited thereto. On the contrary, this patent covers all systems, apparatus, articles of manufacture, and methods fairly falling within the scope of the claims of this patent.

What is claimed is:

1. A semiconductor chip comprising:
a front surface;
a back surface opposite the front surface;
a first lateral surface extending between the front surface and the back surface;
a second lateral surface extending between the front surface and the back surface; and
a curved fillet at an intersection between the first lateral surface and the second lateral surface.

2. The semiconductor chip of claim 1, wherein the curved fillet has a radius of curvature of at least 5 micrometers.

3. The semiconductor chip of claim 1, wherein the curved fillet extends a full distance of a length of the intersection between the first lateral surface and the second lateral surface.

4. The semiconductor chip of claim 1, wherein the curved fillet is a first curved fillet, the semiconductor chip further including:
a third lateral surface between the front surface and the back surface, the third lateral surface opposite the first lateral surface;
a fourth lateral surface between the front surface and the back surface, the fourth lateral surface opposite the second lateral surface;
a second curved fillet at an intersection between the second lateral surface and the third lateral surface;
a third curved fillet at an intersection between the third lateral surface and the fourth lateral surface; and
a fourth curved fillet at an intersection between the fourth lateral surface and the first lateral surface.

5. The semiconductor chip of claim 1, further including a rounded edge along a length of an intersection between the back surface and the first lateral surface.

6. The semiconductor chip of claim 5, wherein the rounded edge has a first radius of curvature and the curved fillet has a second radius of curvature, the first radius of curvature smaller than the second radius of curvature.

7. The semiconductor chip of claim 5, wherein the rounded edge extends around a perimeter of the back surface.

8. An integrated circuit package comprising:
a substrate; and
a semiconductor die carried by the substrate, the semiconductor die having a footprint exhibiting a polygonal shape with rounded corners.

9. The integrated circuit package of claim 8, wherein the semiconductor die includes a first side facing the substrate, a second side opposite the first side, and lateral surfaces between the first side and the second side, the lateral surfaces defining the polygonal shape of the footprint of the semiconductor die.

10. The integrated circuit package of claim 8, wherein the polygonal shape corresponds to a rectangle.

11. The integrated circuit package of claim 8, wherein none of the rounded corners have a radius of curvature less than 2 micrometers.

12. The integrated circuit package of claim 8, wherein the semiconductor die includes a first side facing the substrate, and a second side opposite the first side, a rounded bevel along a perimeter of the second side of the semiconductor die.

13. The integrated circuit package of claim 12, wherein the semiconductor die is a first semiconductor die, the integrated circuit package including:
a second semiconductor die carried by the substrate adjacent the first semiconductor die; and
a dielectric material between the first semiconductor die and the second semiconductor die, the dielectric material in contact with and extending around the rounded bevel.

14. The integrated circuit package of claim 8, wherein the semiconductor die is fusion bonded to the substrate.

15. An apparatus comprising:
a substrate; and
a semiconductor chip coupled to the substrate, the semiconductor chip including a first surface facing the substrate and a second surface facing away from the substrate, the semiconductor chip including a sidewall around a perimeter of the semiconductor chip between the first surface and the second surface, the sidewall devoid of abrupt corners between different segments of the sidewall, the different segments of the sidewall angled relative to one another.

16. The apparatus of claim 15, including rounded corners between the different segments of the sidewall, ones of the rounded corners including a radius of curvature of at least 5 micrometers.

17. The apparatus of claim 15, wherein the different segments correspond to different planar surfaces of the sidewall.

18. The apparatus of claim 15, wherein the semiconductor chip includes a rounded bevel at an interface of the second surface and the sidewall.

19. The apparatus of claim 15, wherein the semiconductor chip is hybrid bonded to the substrate.

20. The apparatus of claim 15, further including at least one of a power source, a keyboard, or a display.
